(19) United States
(12) Patent Application Publication
(10) Pub. No.: US 2023/0046092 A1
(43) Pub. Date: Feb. 16, 2023

(54) DISPLAY APPARATUS

(71) Applicant: Samsung Display Co., Ltd., Yongin-si (KR)

(72) Inventors: Youngwan Seo, Yongin-si (KR); Jisun Kim, Yongin-si (KR); Kyunghoe Lee, Yongin-si (KR); Keunhee Choi, Yongin-si (KR)

(21) Appl. No.: 17/876,788

(22) Filed: Jul. 29, 2022

(30) Foreign Application Priority Data
Aug. 10, 2021 (KR) 10-2021-0105479

(51) Int. Cl. H01L 27/32; G09G 3/3233

(52) U.S. Cl. CPC H01L 27/3248; G09G 3/3233; H01L 27/3262; G09G 2300/0426; G09G 2300/0819; G09G 2300/0842; G09G 2300/0861; G09G 2330/04; G09G 2330/10; H01L 27/124

(57) ABSTRACT

The display apparatus includes a substrate including an auxiliary circuit area and an auxiliary display area, an auxiliary pixel circuit on the auxiliary circuit area, an auxiliary display element on the auxiliary display area, and a connection line extending from the auxiliary circuit area to the auxiliary display area and configured to connect the auxiliary pixel circuit to the auxiliary display element. The connection line includes a first sub-line and a second sub-line which are on different layers, and the first sub-line is electrically connected to the second sub-line through a contact portion.

This application claims priority to Korean Patent Application No. 10-2021-0105479, filed on Aug. 10, 2021, and all the benefits accruing therefrom under 35 U.S.C. §119, the disclosure of which is incorporated by reference herein in its entirety.

### BACKGROUND

### 1. Field

One or more embodiments relate to a display apparatus. More particularly, one or more embodiments relate to a display apparatus in which a display area is expanded so that an image may be displayed even in an area where a component or a driving circuit, which is an electronic element, is arranged.

### 2. Description of the Related Art

In general, display apparatuses include a display element and electronic elements for controlling an electrical signal applied to the display element. The electronic elements include a thin-film transistor (TFT), a storage capacitor, and a plurality of lines.

The use of display apparatuses has diversified. Also, as thicknesses and weights of display apparatuses have decreased, the range of applications of display apparatuses has increased. As the range of use of the display apparatuses is diversified, various methods of designing the shapes of the display apparatuses have been studied.

### SUMMARY

However, in display apparatuses of the related art, as the length of a connection line that connects a pixel circuit to a display element, which are spaced apart from each other, increases, electrical charges are introduced through the connection line, which causes a pixel defect.

In order to solve various problems including the above-described problem, one or more embodiments provide a display apparatus in which the occurrence of a pixel defect due to static electricity is significantly reduced. However, the embodiments are examples, and do not limit the scope of the disclosure.

Additional features and advantages will be set forth in part in the description which follows and, in part, will be apparent from the description, or may be learned by practice of the presented embodiments of the disclosure.

According to one or more embodiments, a display apparatus includes a substrate including an auxiliary circuit area and an auxiliary display area, an auxiliary pixel circuit on the auxiliary circuit area, an auxiliary display element on the auxiliary display area, and a connection line extending from the auxiliary circuit area to the auxiliary display area and configured to connect the auxiliary pixel circuit to the auxiliary display element. The connection line includes a first sub-line and a second sub-line which are on different layers, and the first sub-line is electrically connected to the second sub-line through a contact portion.

According to an embodiment, the auxiliary pixel circuit may include a thin-film transistor and a storage capacitor, the thin-film transistor may include a semiconductor layer, a gate electrode partially overlapping the semiconductor layer and an electrode layer on the gate electrode, and the first sub-line and the gate electrode may be on a same layer.

According to an embodiment, the auxiliary pixel circuit may include a thin-film transistor and a storage capacitor, the thin-film transistor may include a semiconductor layer, a gate electrode partially overlapping the semiconductor layer and an electrode layer on the gate electrode, and the first sub-line and the electrode layer may be on a same layer.

According to an embodiment, the first sub-line and the electrode layer may include different materials.

According to an embodiment, the auxiliary pixel circuit may include a thin-film transistor and a storage capacitor, the thin-film transistor may include a semiconductor layer, a gate electrode partially overlapping the semiconductor layer and an electrode layer on the gate electrode, the display apparatus may further include a conductive layer on the electrode layer, and the first sub-line and the conductive layer may be on a same layer.

According to an embodiment, the auxiliary pixel circuit may include a thin-film transistor and a storage capacitor, the storage capacitor may include a lower electrode and an upper electrode, and the first sub-line and any one of the lower electrode and the upper electrode may be on a same layer.

According to an embodiment, the display apparatus may further include a first planarization insulating layer on the auxiliary pixel circuit and a second planarization insulating layer on the first planarization insulating layer, the first sub-line may be on the first planarization insulating layer, and the second sub-line may be on the second planarization insulating layer.

According to an embodiment, the connection line may further include a third sub-line on a different layer from the first sub-line and the second sub-line, and the third sub-line may be electrically connected to the first sub-line or the second sub-line through a contact portion.

According to an embodiment, the display apparatus may further include an insulating layer between the first sub-line and the second sub-line.

According to an embodiment, the insulating layer may include an inorganic material or an organic material.

According to an embodiment, the auxiliary display element may be provided as a plurality of auxiliary display elements, and the display apparatus may further include an auxiliary electrode line configured to electrically connect any one of the plurality of auxiliary display elements to another of the plurality of auxiliary display elements.

According to an embodiment, the display apparatus may further include a pixel-defining layer on the substrate and defining an auxiliary emission area through an opening thereof, and the connection line may not overlap the emission area.

According to an embodiment, the first sub-line and the second sub-line may be provided as a plurality of first sub-lines and a plurality of second sub-lines, respectively, and the plurality of first sub-lines and the plurality of second sub-lines may be alternated along the connection line and connected to each other.

According to an embodiment, the substrate may further include a main display area and a peripheral area which is outside the main display area, the main display area and the peripheral area being arranged to surround at least a portion of the auxiliary display area, and the auxiliary circuit area may be spaced apart from the auxiliary display area with the main display area therebetween.

According to an embodiment, the peripheral area may include the auxiliary circuit area.

According to an embodiment, the contact portion may be in the main display area.

According to an embodiment, the substrate may further include a main display area and a peripheral area which is outside the main display area, the main display area and the peripheral area being arranged to surround at least a portion of the auxiliary display area, and the auxiliary circuit area may be in contact with one side boundary of the auxiliary display area.

According to an embodiment, at least a portion of the connection line corresponding to the auxiliary display area may include a transparent conductive material.

According to an embodiment, the substrate may further include a main display area including which a main display element and a main pixel circuit, and the auxiliary display area may contact with an outer boundary of the auxiliary circuit area.

According to an embodiment, the display apparatus may further include a driving circuit on the auxiliary display area, and the auxiliary display element may overlap the driving circuit.

The above and other features, and advantages of the embodiments of the disclosure will be more apparent from the following description, the accompanying drawings, and claims.

### BRIEF DESCRIPTION OF THE DRAWINGS

The above and other features and advantages of the disclosure will be more apparent from the following description taken in conjunction with the accompanying drawings, in which:

FIG. 1 is a schematic perspective view of an embodiment of a display apparatus;

FIG. 2 is a schematic plan view of an embodiment of a display panel of the display apparatus of FIG. 1;

FIG. 3 is a schematic cross-sectional view of the display panel shown in FIG. 2, taken along line I-I';

FIG. 4 is a schematic plan view of an embodiment of a display panel of the display apparatus of FIG. 1;

FIG. 5 is a schematic cross-sectional view of the display panel shown in FIG. 4, taken along line II-II';

FIGS. 6 and 7 are equivalent circuit diagrams of embodiments of pixels of a display apparatus;

FIGS. 8A to 8D are cross-sectional views of embodiments of a display panel of a display apparatus;

FIG. 9 is a schematic perspective view of an embodiment of a display apparatus;

FIG. 10 is a schematic plan view of an embodiment of a display panel of the display apparatus of FIG. 9;

FIG. 11 is a cross-sectional view of an embodiment of a portion of the display panel shown in FIG. 10;

FIG. 12 is a schematic plan view of an embodiment of a portion of a display area of the display panel shown in FIG. 10; and

FIGS. 13A to 13D are schematic plan views of embodiments of a portion of a display area.

### DETAILED DESCRIPTION

Reference will now be made in detail to embodiments, examples of which are illustrated in the accompanying drawings, where like reference numerals refer to like elements throughout. In this regard, the present embodiments may have different forms and should not be construed as being limited to the descriptions set forth herein. Accordingly, the embodiments are merely described below, by referring to the figures, to explain features and advantages of the present description.

As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof. As used herein, “a”, “an,” “the,” and “at least one” do not denote a limitation of quantity, and are intended to include both the singular and plural, unless the context clearly indicates otherwise.

As the disclosure allows for various changes and numerous embodiments, embodiments will be illustrated in the drawings and described in the detailed description. The attached drawings for illustrating embodiments of the present disclosure are referred to in order to gain a sufficient understanding of the disclosure, the merits thereof, and the objectives accomplished by the implementation of the disclosure. However, the disclosure is not limited to the following embodiments and may be embodied in various forms.

The embodiments will now be described more fully with reference to the accompanying drawings. When describing embodiments with reference to the accompanying drawings, the same or corresponding elements are denoted by the same reference numerals and a redundant description thereof will be omitted.

It will be understood that although the terms “first,” “second,” etc. may be used herein to describe various elements, these elements should not be limited by these terms. These terms are only used to distinguish one element from another.

In the following embodiments, the singular forms include the plural forms unless the context clearly indicates otherwise. As used herein, a reference number may indicate a singular element or a plurality of the element. For example, a reference number labeling a singular form of an element within the drawing figures may be used to reference a plurality of the singular element within the text of specification.

It will be further understood that the terms “comprises” and/or “comprising” used herein specify the presence of stated features or elements, but do not preclude the presence or addition of one or more other features or elements.

It will be further understood that, when a layer, region, or element is referred to as being related to another element such as being “on” another layer, region, or element, it may be directly on the other layer, region, or element, or may be indirectly on the other layer, region, or element with intervening layers, regions, or elements therebetween. In contrast, when a layer, region, or element is referred to as being related to another element such as being “directly on” another layer, region, or element, no intervening layer, region, or element is present therebetween.

It will be understood that when a layer, region, or element is referred to as being “connected to” another layer, region, or element, it may be “directly connected to” the other layer, region, or element or may be “indirectly connected to” the other layer, region, or element with one or more intervening layers, regions, or elements therebetween. For example, it will be understood that when a layer, region, or element is referred to as being “electrically connected to” another layer, region, or element, it may be “directly electrically connected to” the other layer, region, or element and/or may be “indirectly electrically connected to” the other layer, region, or element with one or more intervening layers, regions, or elements therebetween.

In the present specification, an expression such as “A and/or B” indicates A, B, or A and B. Also, an expression such as “at least one of A and B” indicates A, B, or A and B.

In the present specification, the x-axis, the y-axis, and the z-axis are not limited to three axes of the rectangular coordinate system and may be interpreted in a broader sense. For example, the x-axis, the y-axis, and the z-axis may be perpendicular to one another or may represent different directions that are not perpendicular to one another.

Furthermore, relative terms, such as “lower” or “bottom” and “upper” or “top,” may be used herein to describe one element’s relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

When an embodiment may be implemented differently, a process order may be performed differently from the described order. For example, two consecutively described processes may be performed substantially at the same time or may be performed in an order opposite to the described order.

Sizes of elements in the drawings may be exaggerated or contracted for convenience of explanation. For example, since sizes and thicknesses of elements in the drawings are arbitrarily illustrated for convenience of explanation, the disclosure is not limited thereto.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ± 30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

One or more embodiment of a display apparatus 1 is an apparatus that displays a moving picture or a still image, and may be used not only in mobile phones, smartphones, tablet personal computers (PCs), mobile communication terminals, electronic notebooks, electronic books, portable multimedia players (PMPs), navigations, and ultra-mobile PCs (UMPCs), but also in a display screen of various products such as televisions, laptops, monitors, billboards, and Internet of things (IoT) apparatuses. One or more embodiment of the display apparatus 1 may also be used in wearable apparatuses, such as smart watches, watch phones, glasses-type displays, or head mounted displays (HMDs). One or more embodiment of the display apparatus 1 may also be used as dashboards of automobiles, center information displays (CIDs) on the center fascia or dashboards of automobiles, room mirror displays that replace side mirrors of automobiles, and displays arranged on the rear sides of front seats to serve as entertainment devices for backseat passengers of automobiles.

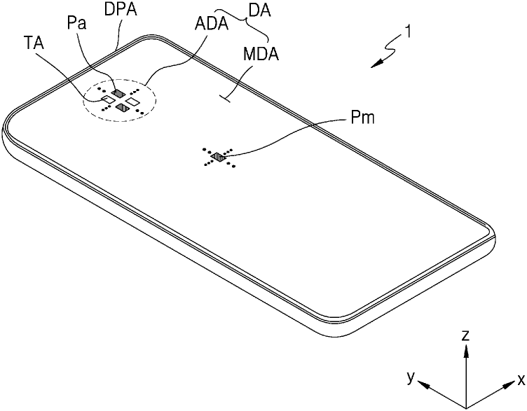

FIG. 1 is a schematic perspective view of an embodiment of a display apparatus 1.

Referring to FIG. 1, the display apparatus 1 may include a display area DA and a peripheral area DPA which is adjacent to the display area DA, such as being outside the display area DA. The display area DA may include an auxiliary display area ADA and a main display area MDA which partially surrounds the auxiliary display area ADA. That is, each of the auxiliary display area ADA and the main display area MDA may display an image individually or together. The peripheral area DPA may be a non-display area in which display elements are not arranged and an image is not displayed. The display area DA may be entirely surrounded by the peripheral area DPA. Various components or layers of the display apparatus 1 may include a display area DA, a peripheral area DPA, a main display area MDA and/or an auxiliary display area ADA corresponding to those described above.

FIG. 1 illustrates that one of the auxiliary display area ADA is located inside the main display area MDA. In another embodiment, the display apparatus 1 may include two or more auxiliary display areas ADA as a plurality of auxiliary display areas ADA. The plurality of auxiliary display areas ADA may have different shapes and sizes, along a plane. The various display areas may be arranged along a plane defined by a first direction and a second direction which cross each other, such as the x-direction and the y-direction. A thickness direction of the display apparatus 1 and/or various layers or components thereof, is defined along a third direction crossing each of the first and second directions (e.g., z-direction).

In a view in a direction substantially perpendicular to the top surface of the display apparatus 1 (e.g., a thickness direction), the auxiliary display area ADA may have various shapes such as a circular shape, an elliptical shape, a polygonal shape such as a rectangular shape, a star shape, or a diamond shape. In addition, FIG. 1 illustrates that the auxiliary display area ADA is arranged at the upper center (in a +y direction) of the main display area MDA substantially having a rectangular shape in a plan view (e.g., in the direction substantially perpendicular to the top surface of the display apparatus 1), however, is not limited thereto. The auxiliary display area ADA may be arranged at one side, for example, at the upper right side or the upper left side in the plan view, of the main display area MDA having a rectangular shape.

The display apparatus 1 may provide an image by using a plurality of main pixels Pm arranged in the main display area MDA, and a plurality of auxiliary pixels Pa arranged in the auxiliary display area ADA.

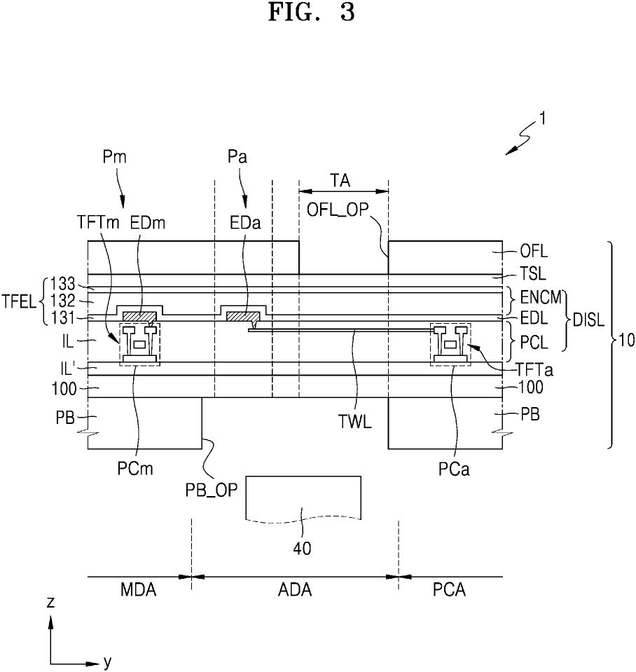

As described below with reference to FIG. 3, in the auxiliary display area ADA, a component 40 as an electronic element which provides a function to the display apparatus 1, may be arranged under a display panel 10 to correspond to the auxiliary display area ADA. The component 40 may include an imaging device such as a camera which provides an imaging function, such as by using infrared light or visible light. Alternatively, the component 40 may include a solar cell, a flash, an illuminance sensor, a proximity sensor, and an iris sensor which provides a power function, a lighting function, a sensing function, etc. Alternatively, the component 40 may have a function of receiving sound. In order to reduce the limitation of the function of the component 40, the auxiliary display area ADA may include a transmission area TA through which light and/or sound output from the component 40 to the outside or directed from the outside to the component 40, may be transmitted. In one or more embodiment of a display panel 10 and a display apparatus 1 including the same, when light is transmitted through the auxiliary display area ADA, the light transmittance at the auxiliary display area ADA may be about 10% or more, such as about 40% or more, about 25% or more, about 50% or more, about 85 % or more, or about 90% more.

A plurality of auxiliary pixels Pa may be arranged in the auxiliary display area ADA. The plurality of auxiliary pixels Pa may provide an image by emitting light (e.g., display pixels). The image displayed in the auxiliary display area ADA is an auxiliary image and may have a resolution lower than that of an image displayed in the main display area MDA (e.g., main image). That is, the auxiliary display area ADA may include a transmission area TA through which light and sound may be transmitted. Where no display pixel is arranged on the transmission area TA, the number of auxiliary pixels Pa in the auxiliary display area ADA that may be arranged per unit area therein may be less than the number of main pixels Pm arranged per unit area in the main display area MDA.

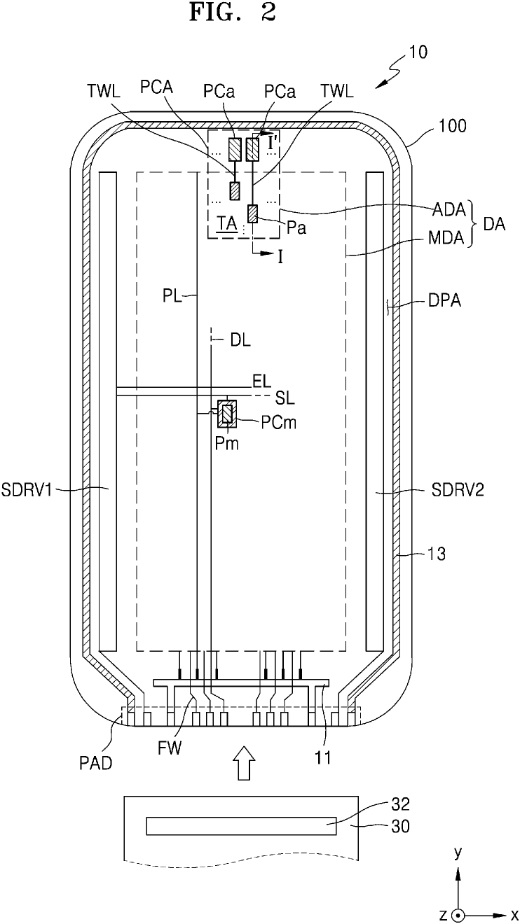

FIG. 2 is a schematic plan view of an embodiment of a display panel 10 in the display apparatus 1 of FIG. 1.

Referring to FIG. 2, various elements constituting the display panel 10 may be arranged on a substrate 100. The substrate 100 may include a display area DA and a peripheral area DPA which surrounds the display area DA. The display area DA may include a main display area MDA in which a main image is displayed, and an auxiliary display area ADA which includes a transmission area TA and in which an auxiliary image is displayed. The auxiliary image may form an entire image together with the main image, and the auxiliary image may be an image independent from the main image.

A plurality of main pixels Pm may be arranged in the main display area MDA. Each of the main pixels Pm may be implemented by a display element ED such as an organic light-emitting diode (OLED). A main pixel circuit PCm driving the main pixels Pm may be arranged in the main display area MDA, and the main pixel circuit PCm may be arranged to overlap (or correspond to) the main pixels Pm. Each main pixel Pm may emit light, for example, red, green, blue, or white light. The main display area MDA may be covered with an encapsulation member ENCM to be protected from external air or moisture.

The auxiliary display area ADA may be located at one or more side of the main display area MDA as described above, or may be arranged inside the display area DA and surrounded by the main display area MDA. A plurality of auxiliary pixels Pa may be arranged in the auxiliary display area ADA. Each of the plurality of auxiliary pixels Pa may be implemented by a display element ED such as an OLED.

An auxiliary pixel circuit PCa driving the auxiliary pixels Pa may be arranged in an auxiliary circuit area PCA. The peripheral area DPA closest to the auxiliary display area ADA may include the auxiliary circuit area PCA. In an embodiment, when the auxiliary display area ADA is arranged above the display area DA, the auxiliary circuit area PCA may be arranged above the peripheral area DPA. The auxiliary pixel circuit PCa may be connected to a display element ED implementing the auxiliary pixels Pa by a connection line TWL extending in a y-direction.

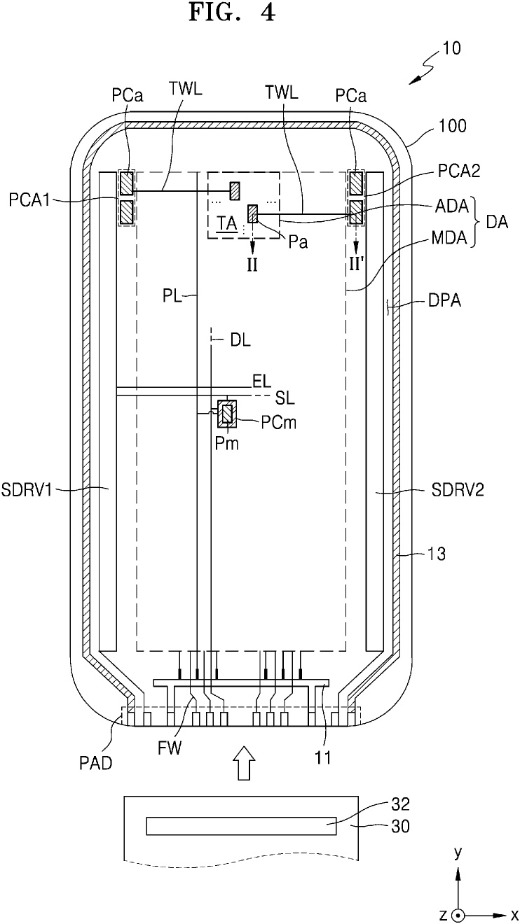

In an embodiment, as described below with reference to FIG. 4, when the auxiliary display area ADA is arranged at the upper center of the display area DA, the auxiliary circuit area PCA may be arranged in the peripheral areas DPA on both of opposing sides with the auxiliary display area ADA therebetween. The auxiliary pixel circuit PCa may be connected to a display element ED implementing the auxiliary pixels Pa by a connection line TWL extending in an x-direction. In this case, the connection line TWL being connected to the display element ED may mean that the connection line TWL is electrically connected to a pixel electrode of the display element ED.

Each auxiliary pixel Pa may emit light, for example, red, green, blue, or white light. The auxiliary display area ADA may be covered with an encapsulation member ENCM to be protected from external air or moisture.

Moreover, the auxiliary display area ADA may include a transmission area TA. The transmission area TA may be arranged to surround a plurality of auxiliary pixels Pa. Alternatively, the transmission area TA may be arranged in a grid form with a plurality of auxiliary pixels Pa.

Since the auxiliary display area ADA includes a transmission area TA, a resolution of the auxiliary display area ADA may be lower than a resolution of the main display area MDA. In an embodiment, for example, the resolution of the auxiliary display area ADA may be about 1/2, 3/8, 1/3, 1/4 2/9, 1/8, 1/9, and 1/16 of the resolution of the main display area MDA. In an embodiment, for example, the resolution of the main display area MDA may be about 400 pixels per inch (ppi) or more, and the resolution of the auxiliary display area ADA may be about 200 ppi or about 100 ppi.

Each of the main and auxiliary pixel circuits PCm and PCa respectively driving the main and auxiliary pixels Pm and Pa may be electrically connected to peripheral circuits arranged in the peripheral area DPA. A first scan driving circuit SDRV1, a second scan driving circuit SDRV2, a terminal portion PAD (e.g., pad area), a driving voltage supply line 11, and a common voltage supply line 13 may be arranged in the peripheral area DPA.

The first scan driving circuit SDRV1 may be configured to apply a scan signal Sn to each of the main pixel circuits PCm driving the main pixels Pm, through a scan line SL. The first scan driving circuit SDRV1 may be configured to apply an emission control signal En to each pixel circuit through an emission control line EL. The second scan driving circuit SDRV2 may be located on the opposite side of the main display area MDA from the first scan driving circuit SDRV1 and may extend to be substantially parallel to the first scan driving circuit SDRV1. Some of the pixel circuits of the main pixels Pm of the main display area MDA may be electrically connected to the first scan driving circuit SDRV1, and the others thereof may be electrically connected to the second scan driving circuit SDRV2.

The terminal portion PAD may be arranged at one side of the substrate 100. The terminal portion PAD is exposed without being covered by an insulating layer. The display panel 10 may be connected to a display circuit board 30 at the terminal portion PAD. A display driver 32 may be arranged at the display circuit board 30.

The display driver 32 may generate an electrical signal such as a control signal to be transmitted to the first scan driving circuit SDRV1 and the second scan driving circuit SDRV2. The display driver 32 may generate an electrical signal such as a data signal Dm, and the generated data signal may be transmitted to the main and auxiliary pixel circuits PCm and PCa through a fan-out line FW and a data line DL connected to the fan-out line FW.

The display driver 32 may supply a driving voltage ELVDD to the driving voltage supply line 11 and may supply a common voltage ELVSS to the common voltage supply line 13. The driving voltage ELVDD may be applied to the main and auxiliary pixel circuits PCm and PCa of the main and auxiliary pixels Pm and Pa, respectively, through a driving voltage line PL connected to the driving voltage supply line 11, and the common voltage ELVSS may be applied to an opposite electrode 230 of the display element ED through the common voltage supply line 13.

The driving voltage supply line 11 may have a major dimension which extends in the x-direction, under the main display area MDA, in the plan view. The common voltage supply line 13 may have a shape in which one side is open in a loop shape, to partially surround the main display area MDA.

Although FIG. 2 illustrates that there is one auxiliary display area ADA, a plurality of auxiliary display areas ADA may be provided. In this case, the plurality of auxiliary display areas ADA may be spaced apart from each other in a direction along the display panel 10, a first camera may be arranged to correspond to one auxiliary display area ADA, and a second camera may be arranged to correspond to another auxiliary display area ADA. Alternatively, a camera may be arranged to correspond to one auxiliary display area ADA, and an infrared sensor may be arranged to correspond to another auxiliary display area ADA. Shapes and sizes of the plurality of auxiliary display areas ADA may be different from each other.

Moreover, the auxiliary display area ADA may have a circular, elliptical, polygonal, or atypical shape, in the plan view. In some embodiments, the auxiliary display area ADA may have an octagonal shape. The auxiliary display area ADA may have various polygonal shapes such as a rectangular shape or a hexagonal shape. The auxiliary display area ADA may be surrounded by the main display area MDA.

FIG. 3 is a schematic cross-sectional view of an embodiment of the display panel 10 shown in FIG. 2, taken along line I-I'.

Referring to FIG. 3, the display apparatus 1 may include the display panel 10 and a component 40 which overlaps (or corresponds to) the display panel 10. A cover window (not illustrated) protecting the display panel 10 may be further arranged over the display panel 10.

The display panel 10 may include an auxiliary display area ADA, which is an area overlapping the component 40, a main display area MDA in which a main image is displayed, and an auxiliary circuit area PCA in which an auxiliary pixel circuit PCa driving an auxiliary light-emitting element EDa is arranged. The display panel 10 may include a substrate 100, a display layer DISL on the substrate 100, a touch screen layer TSL, an optical functional layer OFL, and a panel protection member PB which is arranged under the substrate 100.

The display layer DISL may include a circuit layer PCL including thin-film transistors TFTm and TFTa, a display element layer EDL including light-emitting elements EDm and EDa as display elements, and a thin-film encapsulation layer TFEL or an encapsulation member ENCM such as an encapsulation substrate (not illustrated). Insulating layers IL and IL' may be arranged in the display layer DISL, and between the substrate 100 and the display layer DISL.

The substrate 100 may include an insulating material such as glass, quartz, or a polymer resin. The substrate 100 may be a rigid substrate or a flexible substrate that is bendable, foldable, or rollable.

A main pixel circuit PCm and a main light-emitting element EDm connected thereto may be arranged in the main display area MDA of the display panel 10. The main pixel circuit PCm may include at least one main thin-film transistor TFTm and may control light emission of the main light-emitting element EDm. A main pixel Pm may be implemented by light emission of the main light-emitting element EDm.

The auxiliary light-emitting element EDa may be arranged in the auxiliary display area ADA of the display panel 10 to implement an auxiliary pixel Pa. In the present embodiment, the auxiliary pixel circuit PCa driving the auxiliary light-emitting element EDa may not be arranged in the auxiliary display area ADA but may be arranged in an auxiliary circuit area PCA included in a peripheral area DPA, which is a non-display area. In another embodiment, a portion of the auxiliary circuit area PCA in which the auxiliary pixel circuit PCa is arranged may be included in the main display area MDA or may be located between the main display area MDA and the auxiliary display area ADA. Various modifications may be made. That is, the auxiliary pixel circuit PCa may be arranged not to overlap the auxiliary light-emitting element EDa.

The auxiliary pixel circuit PCa may include at least one auxiliary thin-film transistor TFTa and may be electrically connected to the auxiliary light-emitting element EDa by a connection line TWL. At least a portion of the connection line TWL corresponding to the auxiliary display area ADA may include a transparent conductive material. The auxiliary pixel circuit PCa may control light emission of the auxiliary light-emitting element EDa. The auxiliary pixel Pa may be implemented by light emission of the auxiliary light-emitting element EDa.

Also, an area (e.g., planar area) of the auxiliary display area ADA in which the auxiliary light-emitting element EDa as a display element ED is not arranged, may be referred to as a transmission area TA (e.g., a remaining portion of the auxiliary display area ADA). The transmission area TA may be an area through which light/signal output from the component 40 arranged to correspond to the auxiliary display area ADA, or light/signal input to the component 40, is transmitted. The transmission area TA and the auxiliary light-emitting element EDa may be alternately arranged in the auxiliary display area ADA. The connection line TWL which connects the auxiliary pixel circuit PCa to the auxiliary light-emitting element EDa may be in the circuit layer PCL including the thin-film transistors TFTm and TFTa, or may be between the circuit layer PCL and the display element layer EDL. Since at least a portion of the connection line TWL corresponding to the auxiliary display area ADA may include a transparent conductive material having a high transmittance (e.g., light transmittance), even though the connection line TWL is arranged in the transmission area TA, a transmittance of the transmission area TA may be secured. In the present embodiment, since the auxiliary pixel circuit PCa is not arranged in the auxiliary display area ADA, an area of the transmission area TA may be secured so that a light transmittance may be further improved.

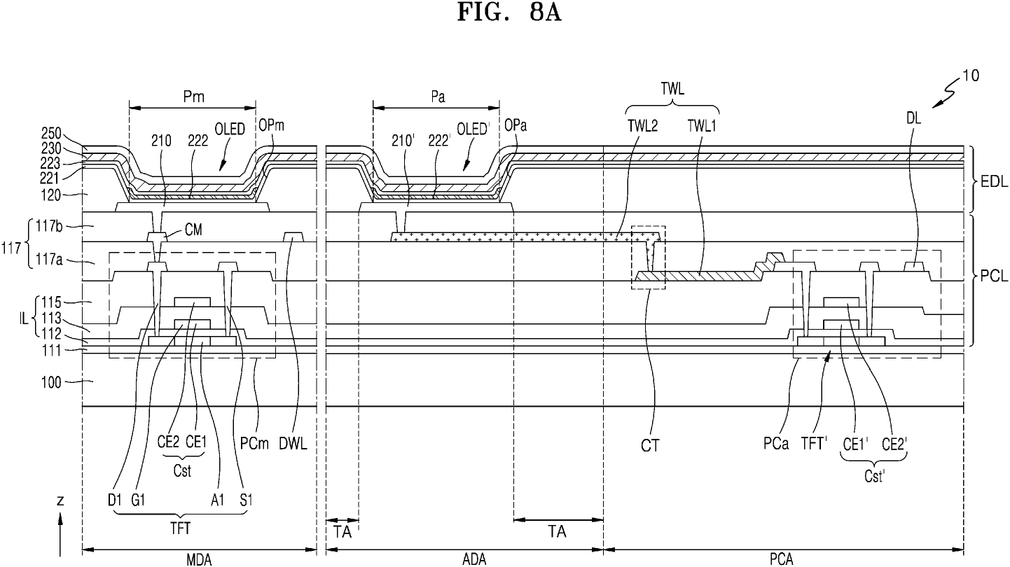

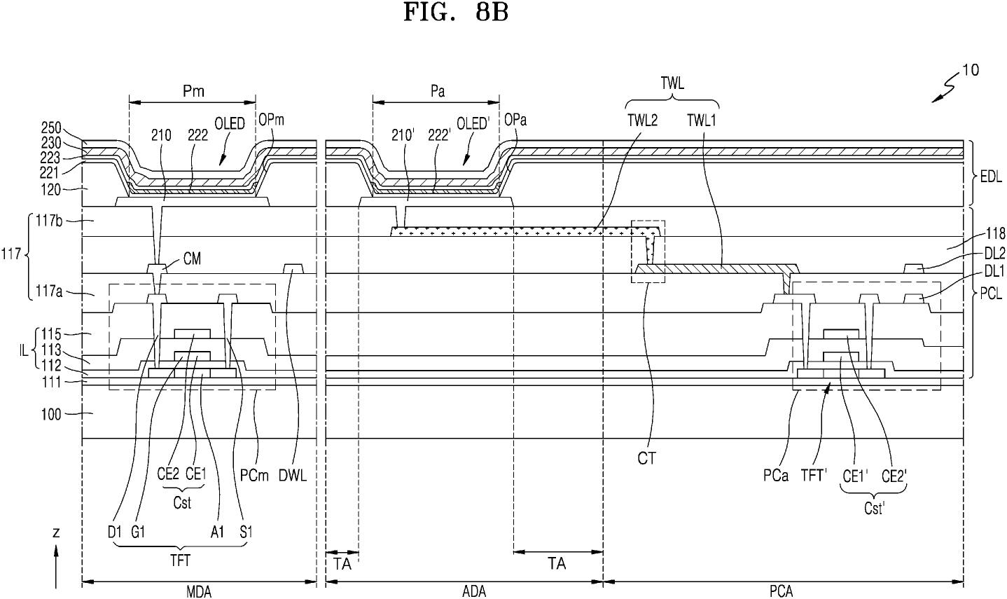

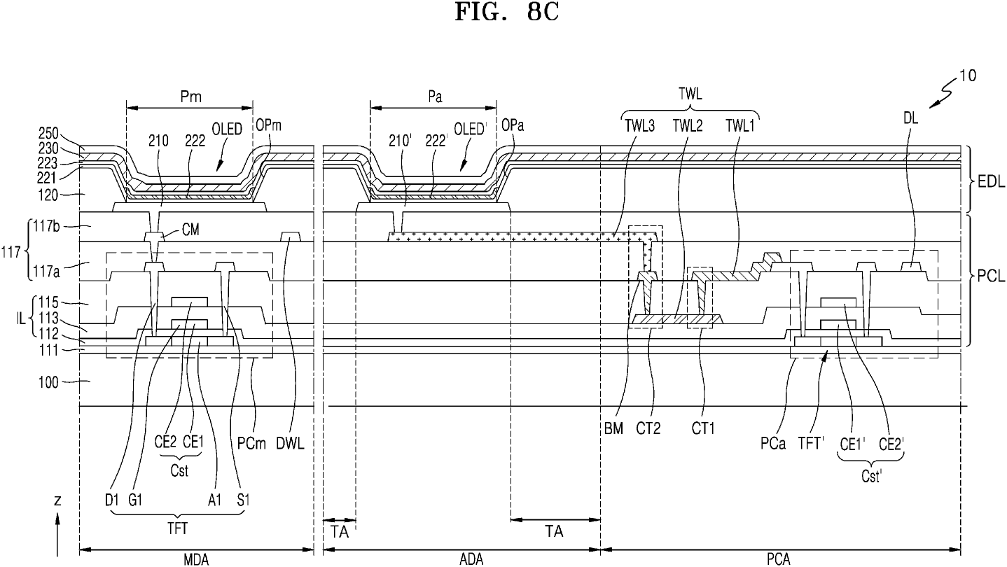

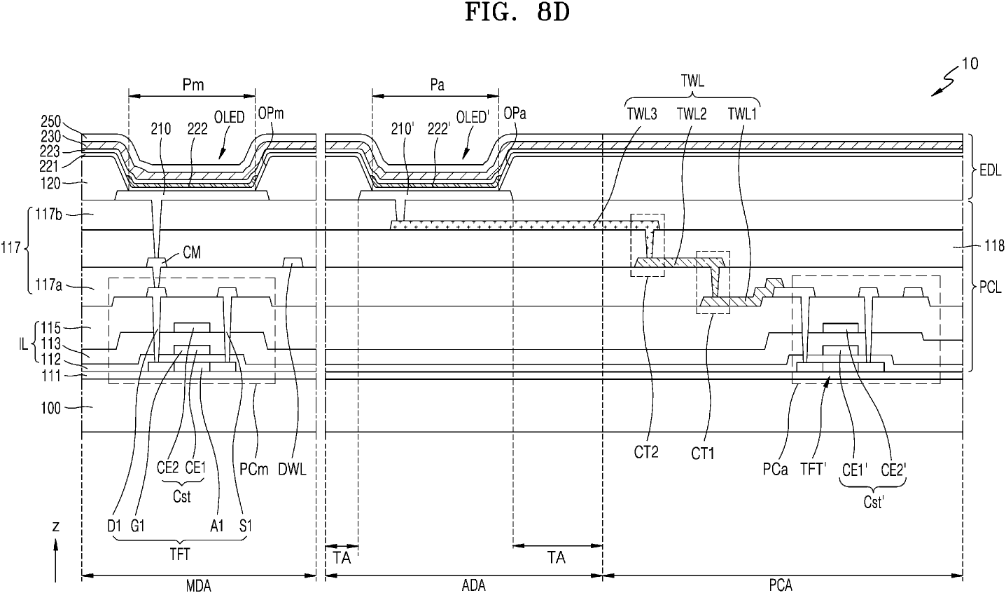

As the length of the connection line TWL increases, electrical charges may be introduced through the connection line TWL during a process, thereby causing a pixel defect due to static electricity. Accordingly, as described with reference to FIGS. 8A to 8D, the connection line TWL may include a plurality of sub-lines arranged on different layers.

The display element layer EDL may be covered by the thin-film encapsulation layer TFEL or the encapsulation substrate. In some embodiments, the thin-film encapsulation layer TFEL may include at least one inorganic encapsulation layer and at least one organic encapsulation layer 132, as illustrated in FIG. 8A. In an embodiment, the thin-film encapsulation layer TFEL may include first and second inorganic encapsulation layers 131 and 133, and an organic encapsulation layer 132 therebetween.

The first inorganic encapsulation layer 131 and the second inorganic encapsulation layer 133 may include one or more inorganic insulating materials such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), or zinc oxide (ZnO), and may be formed (or provided) by chemical vapor deposition (CVD) or the like. The organic encapsulation layer 132 may include a polymer-based material. The polymer-based material may include a silicon-based resin, an acrylic resin, an epoxy-based resin, polyimide, polyethylene, or the like.

The first inorganic encapsulation layer 131, the organic encapsulation layer 132, and the second inorganic encapsulation layer 133 may be formed as a single body extending across both the main display area MDA and the auxiliary display area ADA, to cover the main display area MDA and the auxiliary display area ADA.

When the display element layer EDL is encapsulated by the encapsulation substrate (not illustrated), the encapsulation substrate may be arranged to face the substrate 100 with the display element layer EDL therebetween. A gap may be between the encapsulation substrate and the display element layer EDL. The encapsulation substrate may include glass. A sealant including frit or the like may be between the substrate 100 and the encapsulation substrate, and the sealant may be arranged in the peripheral area DPA described above. The sealant arranged in the peripheral area DPA may surround the display area DA to prevent moisture from penetrating through the side surface of one or more layers of the display panel 10.

The touch screen layer TSL may obtain coordinate information of an external input, in response to an external input, for example, a touch event. The touch screen layer TSL may include a touch electrode and touch lines which are connected to the touch electrode. The touch screen layer TSL may detect an external input by a self-capacitance method or a mutual capacitance method.

The touch screen layer TSL may be formed or provided on the thin-film encapsulation layer TFEL. Alternatively, the touch screen layer TSL may be separately formed on a touch substrate, and then coupled onto the thin-film encapsulation layer TFEL through an adhesive layer as an intervening layer, such as an optically clear adhesive (OCA). In an embodiment, the touch screen layer TSL may be directly formed on the thin-film encapsulation layer TFEL, and in this case, the adhesive layer may not be between the touch screen layer TSL and the thin-film encapsulation layer TFEL.

The optical functional layer OFL may include an anti-reflective layer. The anti-reflective layer may reduce a reflectance of light (external light) incident from the outside the display apparatus 1 and toward the display apparatus 1.

In some embodiments, the optical functional layer OFL may include a polarization film. The optical functional layer OFL may include or define a first opening OFL_OP corresponding to the transmission area TA. Accordingly, the light transmittance of the transmission area TA may be significantly improved by the first opening OFL_OP. The first opening OFL_OP may be filled with a transparent material such as an optically clear resin (OCR).

In some embodiments, the optical functional layer OFL may include a filter plate including a black matrix and color filters.

The panel protection member PB may be attached to the substrate 100 to support and protect the substrate 100. The panel protection member PB may include a second opening PB_OP corresponding to the auxiliary display area ADA. That is the panel protection member PB may be disconnected at the auxiliary display area ADA. Since the panel protection member PB includes the second opening PB_OP, a light transmittance of the auxiliary display area ADA may be improved. The panel protection member PB may include polyethylene terephthalate (PET) or polyimide (PI).

Areas (e.g., planar areas) may be defined along a plane, such as a plane defined by a first direction and a second direction crossing each other. An area of the auxiliary display area ADA may be greater than an area of the component 40. Accordingly, an area of the second opening PB_OP in the panel protection member PB may not be equal to the area of the auxiliary display area ADA.

Also, a plurality of components 40 may be arranged in the auxiliary display area ADA. The plurality of components 40 may have different functions. In an embodiment, for example, the plurality of components 40 may include at least two of a camera (imaging element), a solar cell, a flash, a proximity sensor, an illuminance sensor, and an iris sensor.

In FIG. 3, a bottom metal layer arranged under the auxiliary light-emitting element EDa of the auxiliary display area ADA is not arranged. In an embodiment, the display apparatus 1 may include a bottom metal layer (not illustrated).

The bottom metal layer may be arranged to overlap the auxiliary light-emitting element Eda. The bottom metal layer may be between the substrate 100 and the auxiliary light-emitting element Eda, along the thickness direction. The bottom metal layer may block external light from reaching the auxiliary light-emitting element EDa. Moreover, the bottom metal layer may be formed to correspond to the entire auxiliary display area ADA. In an embodiment, the bottom metal layer may define a lower hole corresponding to the transmission area TA. In this case, the lower hole may have various shapes such as a polygonal, circular, or atypical shape to control diffraction characteristics of external light.

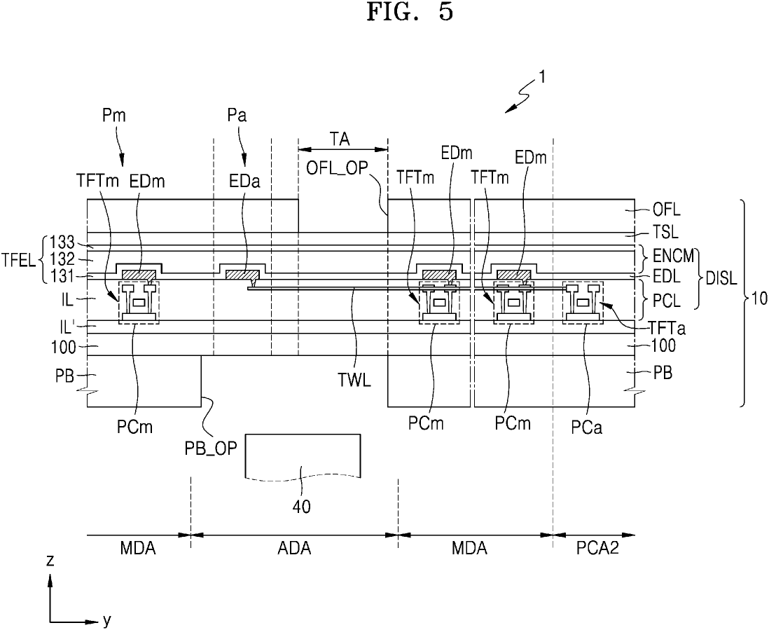

FIG. 4 is a schematic plan view of an embodiment of a display panel 10 that may be included in the display apparatus 1 of FIG. 1, and FIG. 5 is a schematic cross-sectional view of the display panel 10 shown in FIG. 4, taken along line II-II'.

FIGS. 4 and 5 are similar to FIGS. 2 and 3, respectively, but are different from FIGS. 2 and 3 in that the auxiliary display area ADA is arranged at the upper center of the display area DA, and two auxiliary circuit areas PCA1 and PCA2 are arranged to face each other with the auxiliary display area ADA therebetween. Since other configurations are the same as those of the aforementioned embodiment, differences are mainly described below.

The substrate 100 may include a display area DA, and a peripheral area DPA surrounding the display area DA. The display area DA may include a main display area MDA in which a main image is displayed, and an auxiliary display area ADA which includes a transmission area TA and in which an auxiliary image is displayed. The auxiliary image may form an entire image together with the main image, or the auxiliary image may be an image independent from the main image.

As illustrated, the auxiliary display area ADA may be arranged inside the display area DA and may be surrounded by the main display area MDA. In an embodiment, the auxiliary display area ADA may be arranged at the upper or lower center of the display area DA.

A plurality of auxiliary pixels Pa may be arranged in the auxiliary display area ADA. Each of the plurality of auxiliary pixels Pa may be implemented by a display element ED such as an OLED. The auxiliary circuit area PCA which drives the auxiliary pixel Pa may be arranged in a portion of the peripheral area DPA which is closest to the auxiliary display area ADA. In an embodiment, two auxiliary circuit areas PCA1 and PCA2 may be arranged to face each other with the auxiliary display area ADA therebetween. The first auxiliary circuit area PCA1 may be arranged in the peripheral area DPA on the side of the first scan driving circuit SDRV1 and not to overlap the first scan driving circuit SDRV1, and the second auxiliary circuit area PCA2 may be arranged in the peripheral area DPA on the side of the second scan driving circuit SDRV2 and not to overlap the second scan driving circuit SDRV2.

In an embodiment, the auxiliary display area ADA may be arranged to be closer toward one side of the main display area MDA, with respect to the center thereof. The first and second auxiliary circuit areas PCA1 and PCA2 may be arranged to face each other with the auxiliary display area ADA therebetween, or only one auxiliary circuit area PCA may also be arranged at only one side which is close to the auxiliary display area ADA.

Although FIG. 4 illustrates there is one auxiliary display area ADA, a plurality of auxiliary display areas ADA may be provided. In this case, the plurality of auxiliary display areas ADA may be spaced apart from each other, a first camera may be arranged to correspond to one auxiliary display area ADA, and a second camera may be arranged to correspond to another auxiliary display area ADA. Alternatively, a camera may be arranged to correspond to one auxiliary display area ADA, and an infrared sensor may be arranged to correspond to another auxiliary display area ADA. Shapes and sizes of the plurality of auxiliary display areas ADA may be different from each other. An auxiliary circuit area PCA corresponding to each auxiliary display area ADA may be arranged in the peripheral area DPA close to the corresponding auxiliary display area ADA.

The auxiliary pixel circuit PCa may be connected to a display element ED within the auxiliary pixel Pa by a connection line TWL extending in an x-direction. In an embodiment, for example, the connection line TWL may extend from the auxiliary circuit area PCA via the main display area MDA, to the auxiliary display area ADA.

Referring to FIG. 5, the connection line TWL may connect the auxiliary pixel circuit PCa to the auxiliary light-emitting element EDa, via the main display area MDA between the auxiliary display area ADA and the auxiliary circuit area PCA.

A plurality of main pixel circuits PCm and a plurality of main light-emitting elements EDm connected thereto may be arranged in the main display area MDA. The main pixel circuit PCm may include at least one thin-film transistor TFTm and may control light emission of the main light-emitting element EDm.

The connection line TWL may be in the circuit layer PCL including thin-film transistors TFTm and TFTa, or between the circuit layer PCL and the display element layer EDL. As described above, as the length of the connection line TWL increases, in order to prevent a pixel defect from occurring due to static electricity, the connection line TWL may include a plurality of sub-lines arranged on different layers. A portion of the connection line TWL corresponding to the main display area MDA may be arranged on a different layer from elements of the main pixel circuit PCm and the main light-emitting element EDm so as not to cause electrical interference with the main pixel circuit PCm and the main light-emitting element EDm. In an embodiment, for example, the connection line TWL may include sub-lines arranged on different layers. The sub-lines may be alternately arranged not to interfere with elements of the main light-emitting element EDm and the auxiliary light-emitting element Eda, or may be provided to be at least partially curved on a plane.

The transmission area TA and the auxiliary light-emitting element EDa may be alternately arranged in the auxiliary display area ADA. The connection line TWL connecting the auxiliary pixel circuit PCa to the auxiliary light-emitting element EDa may be in the circuit layer PCL including the thin-film transistors TFTm and TFTa, or between the circuit layer PCL and the display element layer EDL. Since at least a portion of the connection line TWL corresponding to the auxiliary display area ADA may include a transparent conductive material having a high light transmittance, even though the connection line TWL is arranged in the transmission area TA, a transmittance of the transmission area TA may be secured.

The arrangement of the auxiliary display area ADA, the auxiliary circuit area PCA, and the connection line TWL is not limited to the number and design of the auxiliary display area ADA, the auxiliary circuit area PCA, and the connection line TWL described with reference to FIGS. 4 and 5, and the number and design thereof may be variously changed, and the arrangement thereof may also be changed accordingly.

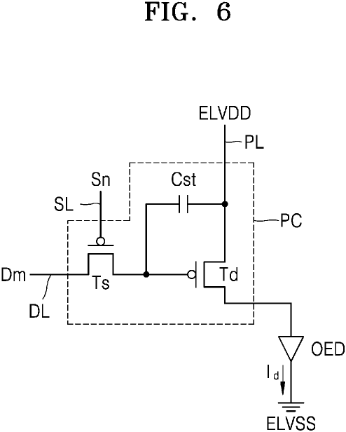

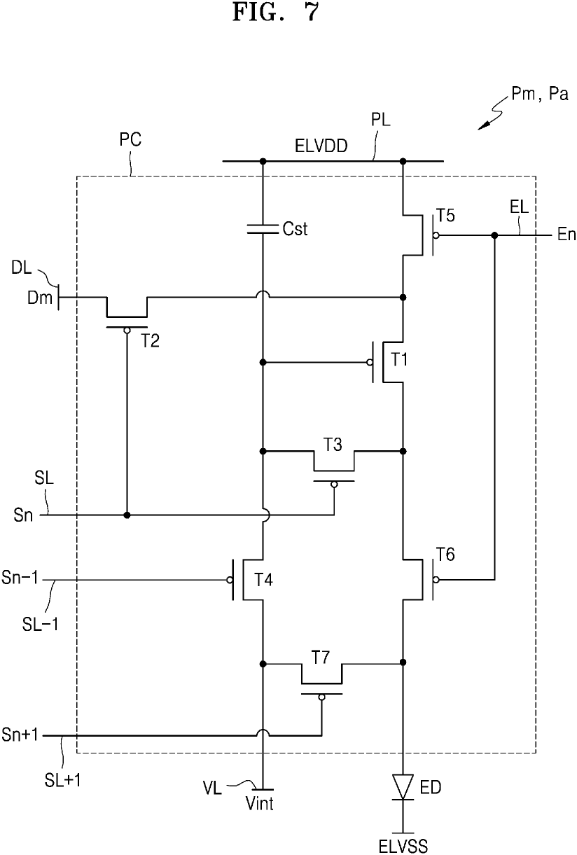

FIGS. 6 and 7 are equivalent circuit diagrams of embodiment of pixels that may be included in a display apparatus 1.

Referring to FIGS. 6 and 7, each of main and auxiliary pixels Pm and Pa may include a pixel circuit PC connected to a scan line SL and a data line DL, and an organic light-emitting diode (OLED) as a display element ED which is connected to the pixel circuit PC (hereinafter organic light-emitting diode OLED). In an embodiment, the main and auxiliary pixels Pm and Pa may include a pixel circuit PC of FIG. 6 or may include a pixel circuit PC of FIG. 7. In an embodiment, for example, the main pixel Pm may include the pixel circuit PC of FIG. 7, and the auxiliary pixel Pa may include the pixel circuit PC of FIG. 6. As another example, both the main pixel Pm and the auxiliary pixel Pa may include the pixel circuit PC of FIG. 7.

The pixel circuit PC of FIG. 6 includes a driving thin-film transistor Td, a switching thin-film transistor Ts, and a storage capacitor Cst. The switching thin-film transistor Ts is connected to the scan line SL and the data line DL and configured to transmit a data signal Dm to the driving thin-film transistor Td in response to a scan signal Sn input through the scan line SL, the data signal Dm being input through the data line DL.

The storage capacitor Cst is connected to the switching thin-film transistor Ts and a driving voltage line PL, and configured to store a voltage corresponding to a difference between a voltage received from the switching thin-film transistor Ts and a driving voltage ELVDD supplied to the driving voltage line PL.

The driving thin-film transistor Td is connected to the driving voltage line PL and the storage capacitor Cst, and may be configured to control a driving current I_{d} flowing through the organic light-emitting diode OLED from the driving voltage line PL in response to the voltage stored in the storage capacitor Cst. The organic light-emitting diode OLED may emit light having a luminance according to a driving current I_{d}.

Although FIG. 6 illustrates that the pixel circuit PC includes two thin-film transistors and one storage capacitor, one or more embodiments are not limited thereto. In another embodiment, the pixel circuit PC may include seven thin-film transistors and one storage capacitor, as illustrated in FIG. 7 described below. In another embodiment, the pixel circuit PC may include two or more storage capacitors.

Referring to FIG. 7, the pixel circuit PC may include a driving thin-film transistor T1, a switching thin-film transistor T2, a compensation thin-film transistor T3, a first initialization thin-film transistor T4, an operation control thin-film transistor T5, an emission control thin-film transistor T6, and a second initialization thin-film transistor T7.

Although FIG. 7 illustrates that each pixel circuit PC includes signal lines SL, SL-1, SL+1, EL, and DL, an initialization voltage line VL, and a driving voltage line PL, one or more embodiments are not limited thereto. In another embodiment, at least one of the signal lines SL, SL-1, SL+1, EL, and DL, and/or the initialization voltage line VL may be shared by adjacent pixel circuits.

A drain electrode of the driving thin-film transistor T1 may be electrically connected to the organic light-emitting diode OLED via the emission control thin-film transistor T6. The driving thin-film transistor T1 is configured to receive a data signal Dm depending on a switching operation of the switching thin-film transistor T2 and supply a driving current to the organic light-emitting diode OLED.

A gate electrode of the switching thin-film transistor T2 is connected to the scan line SL, and a source electrode of the switching thin-film transistor T2 is connected to the data line DL. A drain electrode of the switching thin-film transistor T2 may be connected to a source electrode of the driving thin-film transistor T1 and the driving voltage line PL via the operation control thin-film transistor T5.

The switching thin-film transistor T2 is turned on in response to the scan signal Sn received through the scan line SL and configured to perform a switching operation of transmitting the data signal Dm received through the data line DL to the source electrode of the driving thin-film transistor T1.

A gate electrode of the compensation thin-film transistor T3 may be connected to the scan line SL. A source electrode of the compensation thin-film transistor T3 may be connected to the drain electrode of the driving thin-film transistor T1 and a pixel electrode of the organic light-emitting diode OLED via the emission control thin-film transistor T6. A drain electrode of the compensation thin-film transistor T3 may be connected to any one of the electrodes of the storage capacitor Cst, a source electrode of the first initialization thin-film transistor T4, and the gate electrode of the driving thin-film transistor T1. The compensation thin-film transistor T3 is turned on in response to the scan signal Sn received through the scan line SL and connects the gate electrode and the drain electrode of the driving thin-film transistor T1 to each other, so as to diode-connect the driving thin-film transistor T1.

A gate electrode of the first initialization thin-film transistor T4 may be connected to a previous scan line SL-1. A drain electrode of the first initialization thin-film transistor T4 may be connected to the initialization voltage line VL. The source electrode of the first initialization thin-film transistor T4 may be connected to any one of the electrodes of the storage capacitor Cst, the drain electrode of the compensation thin-film transistor T3 and the gate electrode of the driving thin-film transistor T1. The first initialization thin-film transistor T4 may be turned on in response to a previous scan signal Sn-1 received through the previous scan line SL-1 and may be configured to transmit an initialization voltage Vint to the gate electrode of the driving thin-film transistor T1, thereby performing an initialization operation of initializing a voltage of the gate electrode of the driving thin-film transistor T1.

A gate electrode of the operation control thin-film transistor T5 may be connected to the emission control line EL. A source electrode of the operation control thin-film transistor T5 may be connected to the driving voltage line PL. A drain electrode of the operation control thin-film transistor T5 is connected to the source electrode of the driving thin-film transistor T1 and the drain electrode of the switching thin-film transistor T2.

A gate electrode of the emission control thin-film transistor T6 may be connected to the emission control line EL. A source electrode of the emission control thin-film transistor T6 may be connected to the drain electrode of the driving thin-film transistor T1 and the source electrode of the compensation thin-film transistor T3. A drain electrode of the emission control thin-film transistor T6 may be electrically connected to the pixel electrode of the organic light-emitting diode OLED. The operation control thin-film transistor T5 and the emission control thin-film transistor T6 are simultaneously turned on in response to an emission control signal En received through the emission control line EL, the driving voltage ELVDD is transmitted to the organic light-emitting diode OLED, and the driving current flows through the organic light-emitting diode OLED.

A gate electrode of the second initialization thin-film transistor T7 may be connected to a next scan line SL+1. A source electrode of the second initialization thin-film transistor T7 may be connected to the pixel electrode of the organic light-emitting diode OLED. A drain electrode of the second initialization thin-film transistor T7 may be connected to the initialization voltage line VL. The second initialization thin-film transistor T7 may be turned on in response to a next scan signal Sn+1 received through the next scan line SL+1 and may be configured to initialize the pixel electrode of the organic light-emitting diode OLED.

FIG. 7 illustrates that the first initialization thin-film transistor T4 and the second initialization thin-film transistor T7 are connected to the previous scan line SL-1 and the next scan line SL+1, respectively. However, one or more embodiments are not limited thereto. In another embodiment, the first initialization thin-film transistor T4 and the second initialization thin-film transistor T7 may be both connected to the previous scan line SL-1 and may be driven according to a previous scan signal Sn-1.

The other electrode of the storage capacitor Cst may be connected to the driving voltage line PL. Any one of the electrodes of the storage capacitor Cst may be connected to the gate electrode of the driving thin-film transistor T1, the drain electrode of the compensation thin-film transistor T3, and the source electrode of the first initialization thin-film transistor T4.

An opposite electrode 230 (e.g., a cathode electrode) of the organic light-emitting diode OLED receives a common voltage ELVSS. The organic light-emitting diode OLED receives a driving current from the driving thin-film transistor T1 to emit light.

The pixel circuit PC is not limited to the number and circuit design of the thin-film transistors and the storage capacitor Cst described with reference to FIGS. 6 and 7, and the number and circuit design of the thin-film transistors and the storage capacitor Cst may be variously changed.

FIGS. 8A to 8D are cross-sectional views of embodiments of a portion of a display panel 10 of a display apparatus 1.

Referring to FIG. 8A, a main pixel Pm may be arranged in a main display area MDA, and an auxiliary pixel Pa may be arranged in an auxiliary display area ADA. The auxiliary display area ADA may include transmission areas TA. A main pixel circuit PCm, which includes a main thin-film transistor TFT and a main storage capacitor Cst, and a main organic light-emitting diode OLED, which is a display element ED connected to the main pixel circuit PCm, may be arranged in the main display area MDA. An auxiliary organic light-emitting diode OLED' may be arranged in the auxiliary display area ADA.

An auxiliary pixel circuit PCa including an auxiliary thin-film transistor TFT' and an auxiliary storage capacitor Cst' may be arranged in the auxiliary circuit area PCA. Moreover, a connection line TWL that extends from the auxiliary circuit area PCA to the auxiliary display area ADA and connects the auxiliary pixel circuit PCa to the auxiliary organic light-emitting diode OLED' may be arranged.

In an embodiment, as described above with reference to FIGS. 4 and 5, the main display area MDA (see FIG. 5) may be between the auxiliary display area ADA and the auxiliary circuit area PCA. In an embodiment, for example, the connection line TWL may extend from the auxiliary circuit area PCA, via the main display area MDA, to the auxiliary display area ADA, and connect the auxiliary pixel circuit PCa to the auxiliary organic light-emitting diode OLED'. The connection line TWL may be arranged on a different layer from elements of the main pixel circuit PCm and the main light-emitting element EDm arranged in the main display area MDA, or may be provided to be at least partially curved on a plane so as not to overlap the elements and may be arranged on the same layer as the elements.

In the present embodiment, as organic light-emitting diode as a display element ED is used as an example, but in another embodiment, an inorganic light-emitting element or a quantum dot light-emitting diode may be used as a display element ED.

Hereinafter, a structure in which elements included in the display panel 10 are stacked will be described. The display panel 10 may have a structure in which a substrate 100, a buffer layer 111, a circuit layer PCL, and a display element layer EDL are stacked.

The substrate 100 may include an insulating material such as glass, quartz, or a polymer resin. The substrate 100 may be a rigid substrate or a flexible substrate that is bendable, foldable, or rollable.

The buffer layer 111 may be located over the substrate 100 to reduce or block the penetration of foreign materials, moisture, or external air from the bottom of the substrate 100 and may provide a flat surface over the substrate 100. The buffer layer 111 may include an inorganic material such as oxide or nitride, an organic material, or an organic/inorganic composite and may have a single-layered or multi-layered structure of an inorganic material and an organic material. A barrier layer (not illustrated) for blocking penetration of external air may be further included between the substrate 100 and the buffer layer 111. In some embodiments, the buffer layer 111 may include SiO₂ or SiNx.

The circuit layer PCL may be arranged on the buffer layer 111 and may include the main and auxiliary pixel circuits PCm and PCa, a first gate insulating layer 112, a second gate insulating layer 113, an interlayer insulating layer 115, and a planarization layer 117. The main pixel circuit PCm may include a main thin-film transistor TFT and a main storage capacitor Cst, and the auxiliary pixel circuit PCa may include an auxiliary thin-film transistor TFT' and an auxiliary storage capacitor Cst'.

The main thin-film transistor TFT and the auxiliary thin-film transistor TFT' may be arranged on the buffer layer 111. The main thin-film transistor TFT may include a semiconductor layer A1, a gate electrode G1, a source electrode S1, and a drain electrode D1. The main thin-film transistor TFT may be connected to a main organic light-emitting diode OLED and drive the main organic light-emitting diode OLED. The auxiliary thin-film transistor TFT' may be connected to the auxiliary organic light-emitting diode OLED' and drive the auxiliary organic light-emitting diode OLED'. Since the auxiliary thin-film transistor TFT' has a configuration similar to that of the main thin-film transistor TFT, the description of the main thin-film transistor TFT replaces the description of the auxiliary thin-film transistor TFT'.

The semiconductor layer A1 may be arranged on the buffer layer 111 and may include polysilicon. In another embodiment, the semiconductor layer A1 may include amorphous silicon. In another embodiment, the semiconductor layer A1 may include an oxide of at least one material selected from among indium (In), gallium (Ga), tin (Sn), zirconium (Zr), vanadium (V), hafnium (Hf), cadmium (Cd), germanium (Ge), chromium (Cr), titanium (Ti), and zinc (Zn). The semiconductor layer A1 may include a channel region, and a source region and a drain region doped with impurities.

The first gate insulating layer 112 may cover the semiconductor layer A1. The first gate insulating layer 112 may include an inorganic insulating material, such as SiO₂, SiNₓ, SiON, Al₂O₃, TiO₂, Ta₂O₅, HfO₂, or ZnO₂. The first gate insulating layer 112 may include a single layer or layers including the aforementioned inorganic insulating material.

The gate electrode G1 may be arranged on the first gate insulating layer 112 to overlap the semiconductor layer A1. The gate electrode G1 may include molybdenum (Mo), aluminum (Al), copper (Cu), Ti, or the like and may include a single layer or layers. In an embodiment, for example, the gate electrode G1 may include a single Mo layer.

The second gate insulating layer 113 may cover the gate electrode G1. The second gate insulating layer 113 may include an inorganic insulating material such as SiOₓ, SiNₓ, SiOₓN_{y}, Al₂O₃, TiO₂, Ta₂O₅, HfO₂, or ZnO. The second gate insulating layer 113 may include a single layer or layers including the aforementioned inorganic insulating material.

An upper electrode CE2 of the main storage capacitor Cst and an upper electrode CE2' of the auxiliary storage capacitor Cst' may be arranged on the second gate insulating layer 113. The upper electrode CE2 of the main storage capacitor Cst and an upper electrode CE2' of the auxiliary storage capacitor Cst' may be in a same layer, among layers on the substrate 100. As used herein, elements in a same layer (or on a same layer) may be respective patterns of a same material layer, element coplanar with each other, etc. without being limited thereto.

In the main display area MDA, the upper electrode CE2 of the main storage capacitor Cst may overlap the gate electrode G1 arranged thereunder. The gate electrode G1 and the upper electrode CE2 overlapping each other with the second gate insulating layer 113 therebetween may form the main storage capacitor Cst. The gate electrode G1 may be a lower electrode CE1 of the main storage capacitor Cst.

In the auxiliary circuit area PCA, the upper electrode CE2' of the auxiliary storage capacitor Cst' may overlap a gate electrode of the auxiliary thin-film transistor TFT' arranged thereunder. The gate electrode of the auxiliary thin-film transistor TFT' may be a first lower electrode CE1' of the auxiliary storage capacitor Cst'.

The upper electrodes CE2 and CE2' may include Al, platinum (Pt), palladium (Pd), silver (Ag), magnesium (Mg), gold (Au), nickel (Ni), neodymium (Nd), iridium (Ir), chrome (Cr), calcium (Ca), Mo, Ti, tungsten (W), and/or Cu, and may include a single layer or layers including the aforementioned material.

The interlayer insulating layer 115 may be formed to cover the upper electrodes CE2 and CE2'. The interlayer insulating layer 115 may include SiO₂, SiNₓ, SiON, Al₂O₃, TiO₂, Ta₂O₅, HfO₂, or ZnO₂. The interlayer insulating layer 115 may include a single layer or layers including the aforementioned inorganic insulating material.

A source electrode S1 and a drain electrode D1 may be arranged over the interlayer insulating layer 115. The source electrode S1 and the drain electrode D1 may include a conductive material including Mo, Al, Cu, Ti, or the like and may include a single layer or layers including the aforementioned material. In an embodiment, for example, the source electrode S1 and the drain electrode D1 may have a multi-layered structure of Ti/Al/Ti. Moreover, a data line DL may be arranged on the interlayer insulating layer 115.

The planarization layer 117 may be arranged to cover the source electrodes, the drain electrodes, and the data line DL. The planarization layer 117 may have a flat top surface so that a main pixel electrode 210 and an auxiliary pixel electrode 210', which are arranged on the planarization layer 117, are formed flat.

The planarization layer 117 may include an organic material or an inorganic material and may have a single-layered structure or a multi-layered structure. The planarization layer 117 may include a first planarization layer 117a and a second planarization layer 117b. Accordingly, a conductive pattern such as a signal line or conductive pattern may be formed between the first planarization layer 117a and the second planarization layer 117b, thereby being advantageous for high integration. A connection electrode CM and a data connection line DWL may be arranged on the first planarization layer 117a as conductive patterns.

The planarization layer 117 may include a general-purpose polymer such as benzocyclobutene (BCB), polyimide, hexamethyldisiloxane (HMDSO), polymethyl methacrylate (PMMA) or polystyrene (PS), a polymer derivative having a phenolic group, an acrylic polymer, an imide-based polymer, an acryl ether-based polymer, an amide-based polymer, a fluorine-based polymer, a p-xylene-based polymer, or a vinyl alcohol-based polymer. Moreover, the planarization layer 117 may include an inorganic insulating material such as SiO₂, SiNx, SiON, Al₂O₃, TiO₂, Ta₂O₅, HfO₂, or ZnO₂. When forming the planarization layer 117, chemical mechanical polishing may be performed on the top surface of a layer to provide a flat top surface after the layer is formed.

The first planarization layer 117a may be arranged to cover the main and auxiliary pixel circuits PCm and PCa. The second planarization layer 117b may be arranged on the first planarization layer 117a and may have a flat top surface so that the main and auxiliary pixel electrodes 210 and 210' are formed flat.

The data connection line DWL may be arranged on the first planarization layer 117a. The data connection line DWL may be connected to the data line DL (or a first data line DL1 in FIG. 8B) so that the same signal is applied to pixel circuits driving a main pixel Pm and an auxiliary pixel Pa arranged in the same column of pixels within the display area DA. The data connection line DWL may be arranged in the main display area MDA. The data connection line DWL may be arranged on a different layer from the data line DL and may be connected to the data line DL through contact holes.

The connection line TWL may include a first sub-line TWL1 and a second sub-line TWL2 arranged in different layers from each other, and the first sub-line TWL1 may be electrically connected to the second sub-line TWL2 through a contact portion CT. In an embodiment, for example, one end of the first sub-line TWL1 may be electrically connected to the auxiliary thin-film transistor TFT' of the auxiliary pixel circuit PCa, the other end of the first sub-line TWL1 which is opposite to the one end thereof may be electrically connected to one end of the second sub-line TWL2 through the contact portion CT, and the other end of the second sub-line TWL2 which is opposite to the one end thereof may be electrically connected to the auxiliary pixel electrode 210' of the auxiliary organic light-emitting diode OLED'.

As illustrated in FIG. 8A, the first sub-line TWL1 may be arranged on the interlayer insulating layer 115. In an embodiment, the first sub-line TWL1 may be arranged on the same layer as an electrode layer including the source electrode S1, the drain electrode D1, and the data line DL, such that the first sub-line TWL1, the source electrode S1, the drain electrode D1 and the data line DL are in a same layer.

The first sub-line TWL1 may include a conductive material including Mo, Al, Cu, Ti, or the like, and may include a single layer or layers including the aforementioned material. In an embodiment, in order to reduce damage to the source electrode S1, the drain electrode D1, and/or the data line DL during a patterning process, the first sub-line TWL1 may include a material different from those of the source electrode S1, the drain electrode D1, and/or the data line DL.

The second sub-line TWL2 may be arranged on the first planarization layer 117a. In an embodiment, the second sub-line TWL2 may be arranged on the same layer as the connection electrode CM and the data connection line DWL.

Although FIG. 8A illustrates that the second sub-line TWL2 is provided as a single body from the contact portion CT to the auxiliary pixel electrode 210', one or more embodiments are not limited thereto. At least a part of the second sub-line TWL2 corresponding to the auxiliary display area ADA or all of the second sub-line TWL2 may include a transparent conductive material. In an embodiment, for example, a part or all of the second sub-line TWL2 may include a transparent conducting oxide (TCO). The TCO may include indium tin oxide (ITO), indium zinc oxide (IZO), zinc oxide (ZnO), indium oxide (ln₂O₃), indium gallium oxide (IGO), or aluminum zinc oxide (AZO). In an embodiment, the second sub-line TWL2 corresponding to the auxiliary circuit area PCA or the main display area MDA may include a conductive material including Mo, Al, Cu, Ti, or the like and may include layers or a single layer including the aforementioned material. Accordingly, electrical resistance of the connection line TWL may be significantly reduced.

The first sub-line TWL1 may be electrically connected to the second sub-line TWL2 at the contact portion CT. Via the contact portion CT, the second sub-line TWL2 may be electrically connected to the first sub-line TWL1 through a contact hole of the first planarization layer 117a. In an embodiment, in order to prevent a decrease in light transmittance of the auxiliary display area ADA, the contact portion CT may be located in the auxiliary circuit area PCA or the main display area MDA.

In an embodiment, the first sub-line TWL1 and the second sub-line TWL2 may be provided as a plurality of first sub-lines TWL1 and a plurality of second sub-lines TWL2, respectively. The plurality of first sub-lines TWL1 and the plurality of second sub-lines TWL2 may be alternately connected to each other to prevent (electrical) interference with elements of the main and auxiliary pixel circuits PCm and PCa and the main and auxiliary organic light-emitting diodes OLED and OLED', and other lines, which are arranged in the main and auxiliary display areas MDA and ADA through which the connection line TWL passes. In an embodiment, for example, the connection line TWL includes the first sub-line TWL1 in an area corresponding to main pixels Pm, so that interference of the main pixel Pm due to the connection line TWL may be significantly reduced.

The main and auxiliary organic light-emitting diodes OLED and OLED' may be arranged on the second planarization layer 117b. The main pixel electrode 210 of the main organic light-emitting diode OLED may be connected to the main pixel circuit PCm through the connection electrode CM arranged on the first planarization layer 117a. The auxiliary pixel electrode 210' of the auxiliary organic light-emitting diode OLED' may be connected to the auxiliary pixel circuit PCa through the connection line TWL including the first sub-line TWL1 and the second sub-line TWL2 which are arranged on the first planarization layer 117a.

The main pixel electrode 210 and the auxiliary pixel electrode 210' may each include a conductive oxide such as ITO, IZO, ZnO, ln₂O₃, IGO, or AZO. The main pixel electrode 210 and the auxiliary pixel electrode 210' may each include a reflective layer including Ag, Mg, Al, Pt, Pd, Au, Ni, Nd, lr, Cr, or any compound thereof. In an embodiment, for example, the main pixel electrode 210 and the auxiliary pixel electrode 210' may each have a structure including layers including ITO, IZO, ZnO, or ln₂O₃ above or under the aforementioned reflective layer. In this case, the main pixel electrode 210 and the auxiliary pixel electrode 210' may each have a stacked structure of ITO/Ag/ITO.

A pixel-defining layer 120 may cover edges of the main pixel electrode 210 and the auxiliary pixel electrode 210' on the planarization layer 117 and may include a main opening OPm and an auxiliary opening OPa respectively exposing a central portion of the main pixel electrode 210 and a central portion of the auxiliary pixel electrode 210'. The main opening OPm and the auxiliary opening OPa define sizes and shapes of light emission areas of the main and auxiliary organic light-emitting diodes OLED and OLED', that is, sizes and shapes of the main and auxiliary pixels Pm and Pa, respectively.

The pixel-defining layer 120 may prevent an electric arc or the like from occurring on the edges of the main and auxiliary pixel electrodes 210 and 210' by increasing a distance between the edges of the main and auxiliary pixel electrodes 210 and 210', and an opposite electrode 230 above the main and auxiliary pixel electrodes 210 and 210'. The pixel-defining layer 120 may include an organic insulating material such as polyimide, polyamide, an acrylic resin, benzocyclobutene, HMDSO, or a phenolic resin and may be formed by spin coating or the like.

A first emission layer 222 and a second emission layer 222' formed to respectively correspond to the main pixel electrode 210 and the auxiliary pixel electrode 210' may be respectively arranged in the main opening OPm and the auxiliary opening OPa of the pixel-defining layer 120. Each of the first emission layer 222 and the second emission layer 222' may include a polymer material or a low molecular weight material and may emit red, green, blue, or white light.

Organic functional layers 221 and 223 may be arranged on and/or under the first emission layer 222 and the second emission layer 222'. The organic functional layers 221 and 223 may include a first functional layer 221 and/or a second functional layer 223. The first functional layer 221 or the second functional layer 223 may be omitted.

The first functional layer 221 may be arranged under the first emission layer 222 and the second emission layer 222'. The first functional layer 221 may include a single layer or layers including an organic material. The first functional layer 221 may include a hole transport layer (HTL) having a single-layered structure. Alternatively, the first functional layer 221 may include a hole injection layer (HIL) and an HTL. The first functional layer 221 may be formed as a single body to correspond to the main and auxiliary organic light-emitting diodes OLED and OLED' respectively included in the main display area MDA and the auxiliary display area ADA.

The second functional layer 223 may be arranged on the first emission layer 222 and the second emission layer 222'. The second functional layer 223 may include a single layer or layers including an organic material. The second functional layer 223 may include an electron transport layer (ETL) and/or an electron injection layer (ElL). The second functional layer 223 may be formed as a single body to correspond to the main and auxiliary organic light-emitting diodes OLED and OLED' respectively included in the main display area MDA and the auxiliary display area ADA.

The opposite electrode 230 may be arranged on the second functional layer 223. The opposite electrode 230 may include a conductive material having a low work function. In an embodiment, for example, the opposite electrode 230 may include a (semi-)transparent layer including Ag, Mg, Al, Pt, Pd, Au, Ni, Nd, lr, Cr, Li, Ca, or any alloy thereof. Alternatively, the opposite electrode 230 may further include a layer, such as ITO, IZO, ZnO, or In₂O₃, on the (semi-)transparent layer including the aforementioned material. The opposite electrode 230 may be formed as a single body to correspond to the main and auxiliary organic light-emitting diodes OLED and OLED' respectively included in the main display area MDA and the auxiliary display area ADA.

Layers from the main pixel electrode 210 to the opposite electrode 230 formed in the main display area MDA may constitute the main organic light-emitting diode OLED. Layers from the auxiliary pixel electrode 210' to the opposite electrode 230 formed in the auxiliary display area ADA may constitute the auxiliary organic light-emitting diode OLED'.

An upper layer 250 including an organic material may be formed on the opposite electrode 230. The upper layer 250 may be a layer provided to protect the opposite electrode 230 and increase light extraction efficiency. The upper layer 250 may include an organic material having a refractive index higher than that of the opposite electrode 230. Alternatively, the upper layer 250 may be provided by stacking layers having different refractive indices. In an embodiment, for example, the upper layer 250 may be provided by stacking a high refractive index layer/a low refractive index layer/a high refractive index layer. In this case, a refractive index of the high refractive index layer may be about 1.7 or more, and a refractive index of the low refractive index layer may be about 1.3 or less.

The upper layer 250 may further include lithium fluoride (LiF). Alternatively, the upper layer 250 may additionally include an inorganic insulating material such as SiO₂ or SiNx.

Although FIG. 8B is similar to FIG. 8A, there is a difference in that the first sub-line TWL1 is arranged on the first planarization layer 117a, and an insulating layer 118 is further included between the first sub-line TWL1 and the second sub-line TWL2.

Referring to FIG. 8B, the first sub-line TWL1 may be arranged on the first planarization layer 117a. In an embodiment, for example, the first sub-line TWL1 may be arranged on the same layer as the connection electrode CM, the data connection line DWL. In an embodiment, the first sub-line TWL1 may include a conductive material different from those of the connection electrode CM and/or the data connection line DWL.

The insulating layer 118 may be arranged on the first planarization layer 117a to cover the first sub-line TWL1. In an embodiment, the insulating layer 118 may include an inorganic insulating material. In this case, the inorganic insulating material may include an inorganic insulating material such as SiO₂, SiNₓ, SiOₓN_{y}, Al₂O₃, TiO₂, Ta₂O₅, HfO₂, or ZnO. In another embodiment, the insulating layer 118 may include an organic insulating material. In this case, the organic insulating material may include a general-purpose polymer such as BCB, polyimide, HMDSO, PMMA or PS, a polymer derivative having a phenolic group, an acrylic polymer, an imide-based polymer, an acryl ether-based polymer, an amide-based polymer, a fluorine-based polymer, a p-xylene-based polymer, or a vinyl alcohol-based polymer. In an embodiment, for example, the insulating layer 118 may include the same material as the first planarization layer 117a and/or the second planarization layer 117b.

The second sub-line TWL2 may be arranged on the insulating layer 118. At least a portion of the second sub-line TWL2 corresponding to the auxiliary display area ADA may include a transparent conductive material. The second sub-line TWL2 is arranged on the insulating layer 118 and arranged on a different layer from the first sub-line TWL1, and may not interfere with the main and auxiliary organic light-emitting diodes OLED and OLED', the main and auxiliary pixel circuits PCm and PCa, and the data line DL and the data connection line DWL.

As described above, the first sub-line TWL1 may be electrically connected to the second sub-line TWL2 through the contact portion CT. In the contact portion CT, the second sub-line TWL2 may be electrically connected to the first sub-line TWL1 through a contact hole of the insulating layer 118. In an embodiment, in order to prevent a decrease in light transmittance of the auxiliary display area ADA, the contact portion CT may be located in the auxiliary circuit area PCA or the main display area MDA.

The auxiliary pixel electrode 210' of the auxiliary organic light-emitting diode OLED' may be connected to the auxiliary pixel circuit PCa through the connection line TWL including the first sub-line TWL1 and the second sub-line TWL2.

In an embodiment, the first sub-line TWL1 and the second sub-line TWL2 may be provided as a plurality of first sub-lines TWL1 and a plurality of second sub-lines TWL2, respectively, and the plurality of first sub-lines TWL1 and the plurality of second sub-lines TWL2 may be alternately connected to each other to prevent interference with the elements of the main and auxiliary pixel circuits PCm and PCa and the main and auxiliary organic light-emitting diodes OLED and OLED', which are arranged in the main and auxiliary display areas MDA and ADA through which the connection line TWL passes.

Referring to FIG. 8C, the connection line TWL may include the first sub-line TWL1, the second sub-line TWL2, and a third sub-line TWL3. The first sub-line TWL1 may be arranged on the interlayer insulating layer 115. In an embodiment, for example, the first sub-line TWL1 may be arranged on the same layer as the source electrode S1, the drain electrode D1, and the data line DL.

The second sub-line TWL2 may be arranged on the second gate insulating layer 113. For example, the second sub-line TWL2 may be arranged on the same layer as the upper electrode CE2. In another embodiment, the second sub-line TWL2 may be arranged on the first gate insulating layer 112. In an embodiment, for example, the second sub-line TWL2 may be arranged on the same layer as the gate electrode G1 and/or the lower electrode CE1.

The second sub-line TWL2 may include a conductive material including Mo, Al, Cu, Ti, or the like, and may include a single layer or layers including the aforementioned material. In an embodiment, the second sub-line TWL2 may include a material different from those of elements of the main and auxiliary pixel circuits PCm and PCa which are arranged on the same layer.

The third sub-line TWL3 may be arranged on the second planarization layer 117b. In another embodiment, as illustrated in FIG. 8B, the third sub-line TWL3 may be arranged on the insulating layer 118 (see FIG. 8B). At least a part or all of the third sub-line TWL3 corresponding to the auxiliary display area ADA may include a transparent conductive layer.

The first sub-line TWL1 may be electrically connected to the second sub-line TWL2 through a first contact portion CT1. The second sub-line TWL2 may be electrically connected to the third sub-line TWL3 through a second contact portion CT2. In an embodiment, in the second contact portion CT2, the connection line TWL may further include a bridge metal BM (e.g., bridge) arranged on the interlayer insulating layer 115 for electrical connection between the second sub-line TWL2 and the third sub-line TWL3. In another embodiment, in the second contact portion CT2, the second sub-line TWL2 may be electrically connected to the first sub-line TWL1, and in a third contact portion (not illustrated), the first sub-line TWL1 may be electrically connected to the third sub-line TWL3.

In an embodiment, the first sub-line TWL1, the second sub-line TWL2, and the third sub-line TWL3 may be provided as a plurality of first sub-lines TWL1, a plurality of second sub-lines TWL2, and a plurality of third sub-lines TWL3, respectively, and the plurality of first sub-lines TWL1, the plurality of second sub-lines TWL2, and the plurality of third sub-lines TWL3 may be alternately connected to each other to prevent interference with the elements of the main and auxiliary pixel circuits PCm and PCa and the main and auxiliary organic light-emitting diodes OLED and OLED', which are arranged in the main and auxiliary display areas MDA and ADA through which the connection line TWL passes. In this case, when the first, second, and third sub-lines TWL1, TWL2, and TWL3 are connected through a plurality of layers, the bridge metal BM may be further included for electrical connection between the first, second, and third sub-lines TWL1, TWL2, and TWL3.

Referring to FIG. 8D, the connection line TWL may include the first sub-line TWL1, the second sub-line TWL2, and the third sub-line TWL3. The first sub-line TWL1 may be arranged on the interlayer insulating layer 115. In an embodiment, for example, the first sub-line TWL1 may be arranged on the same layer as the source electrode S1, the drain electrode D1, and the data line DL.

The second sub-line TWL2 may be arranged on the first planarization layer 117a. In an embodiment, for example, the second sub-line TWL2 may be arranged on the same layer as the connection electrode CM and the data connection line DWL.

The third sub-line TWL3 may be arranged on the insulating layer 118. The insulating layer 118 may be a layer added to avoid interference of the third sub-line TWL3 with the elements of the main and auxiliary pixel circuits PCm and PCa, elements of the main and auxiliary organic light-emitting diodes OLED and OLED' and elements of the data line DL and the data connection line DWL. In an embodiment, the insulating layer 118 may include an inorganic insulating material. In another embodiment, the insulating layer 118 may include an organic insulating material. In an embodiment, for example, the insulating layer 118 may include the same material as the first planarization layer 117a or the second planarization layer 117b.

The first sub-line TWL1 may be electrically connected to the second sub-line TWL2 through the first contact portion CT1. The second sub-line TWL2 may be electrically connected to the third sub-line TWL3 through the second contact portion CT2.

In an embodiment, the first sub-line TWL1, the second sub-line TWL2, and the third sub-line TWL3 may be provided as a plurality of first sub-lines TWL1, a plurality of second sub-lines TWL2, and a plurality of third sub-lines TWL3, respectively, and the plurality of first sub-lines TWL1, the plurality of second sub-lines TWL2, and the plurality of third sub-lines TWL3 may be alternately connected to each other to prevent interference with the elements of the main and auxiliary pixel circuits PCm and PCa and the main and auxiliary organic light-emitting diodes OLED and OLED', which are arranged in the main and auxiliary display areas MDA and ADA through which the connection line TWL passes. In this case, when the first, second, and third sub-lines TWL1, TWL2, and TWL3 are connected through a plurality of layers, the bridge metal BM may be further included for electrical connection between the first, second, and third sub-lines TWL1, TWL2, and TWL3.

In FIG. 8D, the display panel 10 is illustrated, in which one insulating layer 118 is between the first planarization layer 117a and the second planarization layer 117b, and the connection line TWL includes the first sub-line TWL1, the second sub-line TWL2, and the third sub-line TWL3, but one or more embodiments are not limited thereto. The display panel 10 may include a plurality of insulating layers, and the connection line TWL may include a greater number of sub-lines arranged on different layers.

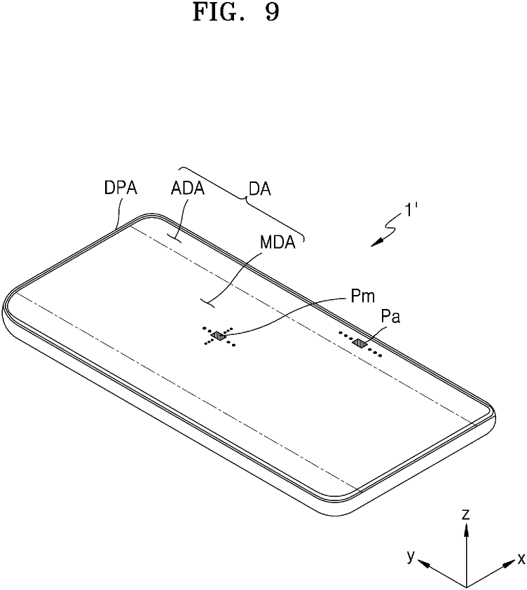

FIG. 9 is a schematic perspective view of an embodiment of a display apparatus 1'.

Referring to FIG. 9, the display apparatus 1' may include a display area DA and a peripheral area DPA which is outside the display area DA. The display area DA may include a main display area MDA and an auxiliary display area ADA which is arranged outside the main display area MDA. That is, each of the main display area MDA and the auxiliary display area ADA may display an image individually or together. The peripheral area DPA may be a type of non-display area in which display elements are not arranged. The display area DA may be entirely surrounded by the peripheral area DPA.

Although FIG. 9 illustrates that two auxiliary display areas ADA are located on both of opposing sides of the main display area MDA along the x-direction, one or more embodiments are not limited thereto. In another embodiment, the display apparatus 1' may further include an auxiliary display area ADA located above and/or under the main display area MDA along the y-direction.

The display apparatus 1' may provide an image by using a plurality of main pixels Pm arranged in the main display area MDA, and a plurality of auxiliary pixels Pa arranged in the auxiliary display area ADA.

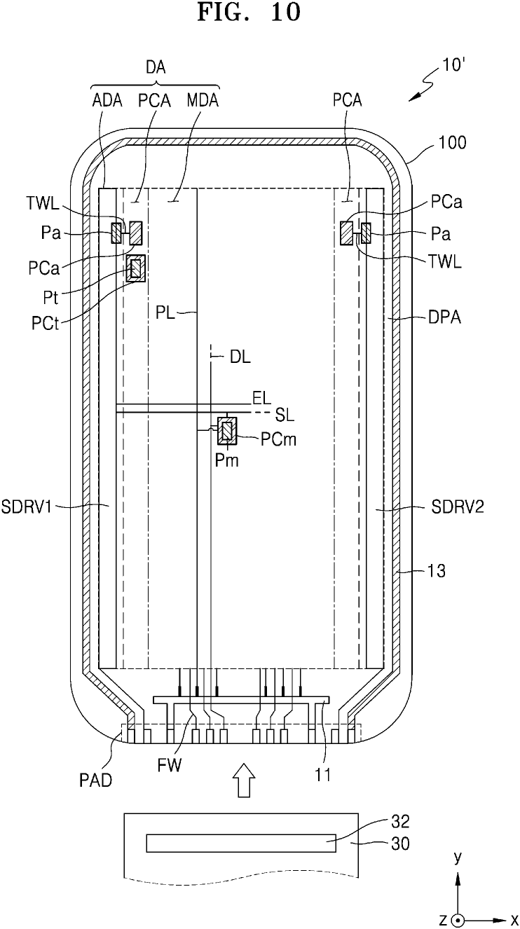

As described below with reference to FIG. 10, the auxiliary pixels Pa may be arranged in the auxiliary display area ADA to partially overlap a driving circuit including a first scan driving circuit SDRV1, a second scan driving circuit SDRV2, and a common voltage supply line 13. In an embodiment, for example, a display element ED of the auxiliary pixels Pa, for example, an organic light-emitting diode OLED' may be arranged above the auxiliary display area ADA, and the driving circuit may be arranged under the auxiliary display area ADA.

A plurality of auxiliary pixels Pa may be arranged in the auxiliary display area ADA. The plurality of auxiliary pixels Pa may provide an image by emitting light. The image displayed in the auxiliary display area ADA is an auxiliary image and may have a resolution lower than that of an image displayed in the main display area MDA. That is, the number of auxiliary pixels Pa that may be arranged per unit area in the auxiliary display area ADA may be less than the number of main pixels Pm arranged per unit area in the main display area MDA.

FIG. 10 is a schematic plan view of an embodiment of a display panel 10' that may be included in the display apparatus 1' of FIG. 9.

Referring to FIG. 10, various elements constituting the display panel 10' may be arranged on a substrate 100. The substrate 100 may include a display area DA and a peripheral area DPA which surrounds the display area DA. The display area DA may include a main display area MDA in which a main image is displayed, an auxiliary display area ADA in which an auxiliary image is displayed, and an auxiliary circuit area PCA. The auxiliary image may form an entire image together with the main image, or the auxiliary image may be an image independent from the main image.

A plurality of main pixels Pm may be arranged in the main display area MDA. Each of the main pixels Pm may be implemented by a display element ED such as an OLED. A main pixel circuit PCm driving the main pixels Pm may be arranged in the main display area MDA, and the main pixel circuit PCm may be arranged to overlap the main pixels Pm. Each main pixel Pm may emit light, for example, red, green, blue, or white light. The main display area MDA may be covered with an encapsulation member ENCM to be protected from external air or moisture.

The auxiliary circuit area PCA may be between the main display area MDA and the auxiliary display area ADA, within the display area DA. Accordingly, a plurality of intermediate pixels Pt and a plurality of auxiliary pixel circuits PCa are arranged in the auxiliary circuit area PCA. That is, an intermediate pixel circuit PCt driving an intermediate pixel Pt, a main organic light-emitting diode OLED, and an auxiliary pixel circuit PCa are arranged in the auxiliary circuit area PCA. In the auxiliary circuit area PCA, the number of intermediate pixels Pt that may be arranged per unit area the auxiliary circuit area PCA may be less than the number of main pixels Pm that may be arranged per unit area of the main display area MDA. Each intermediate pixel Pt may emit light, for example, red, green, blue, or white light. The auxiliary circuit area PCA may be covered with an encapsulation member ENCM to be protected from external air or moisture.

In an embodiment, the intermediate pixel Pt and the main pixel Pm may have different sizes (or widths) in one or more directions along a plane of the display panel 10'. In an embodiment, for example, a size the intermediate pixel Pt may be greater than a size the main pixel Pm, and may be arranged to overlap the intermediate pixel circuit PCt and the auxiliary pixel circuit PCa.

In another embodiment, the intermediate pixel Pt may have the same size as the main pixel Pm, but the plurality of intermediate pixels Pt emitting the same color may be electrically connected to each other through electrode lines. The plurality of intermediate pixels Pt electrically connected through the electrode lines may be connected to one intermediate pixel circuit PCt and driven in common. The intermediate pixel Pt may be arranged to overlap the intermediate pixel circuit PCt and the auxiliary pixel circuit PCa.

As described above, the auxiliary display area ADA may be located on both of opposing sides of the main display area MDA or may surround at least a portion of the outside of the main display area MDA. The auxiliary display area ADA may be located in contact with a boundary of the auxiliary circuit area PCA. Display elements of the plurality of auxiliary pixels Pa are arranged in the auxiliary display area ADA. Each of the plurality of auxiliary pixels Pa may be implemented by a display element ED such as an OLED. The auxiliary pixel circuit PCa driving the auxiliary pixel Pa may be arranged in the auxiliary circuit area PCA which is close to the auxiliary display area ADA.

The auxiliary pixel circuit PCa may be connected to a display element ED implementing the auxiliary pixel Pa, by a connection line TWL extending in the x-direction. The connection line TWL being connected to the display element ED may mean that the connection line TWL is electrically connected to a pixel electrode of the display element ED.

Each auxiliary pixel Pa may emit light, for example, red, green, blue, or white light. The auxiliary display area ADA may be covered with an encapsulation member ENCM to be protected from external air or moisture.

Each of pixel circuits driving the main, intermediate, and auxiliary pixels Pm, Pt, and Pa may be electrically connected to driving circuits arranged outside the display area DA. The driving circuits may include a first scan driving circuit SDRV1, a second scan driving circuit SDRV2, and a common voltage supply line 13. As described above, at least some of the driving circuits may be arranged in the auxiliary display area ADA and may overlap a display element ED of the auxiliary pixel Pa. As the display element ED of the auxiliary pixel Pa is arranged and overlaps on at least some elements of the driving circuit, the area of the display area DA may be increased. A terminal portion PAD and a driving voltage supply line 11 may be further arranged in the peripheral area DPA.

The first scan driving circuit SDRV1 may be configured to apply a scan signal Sn to each of the main and auxiliary pixel circuits PCm and PCa respectively driving the main pixels Pm and the auxiliary pixels Pa, through the scan line SL. The first scan driving circuit SDRV1 may be configured to apply an emission control signal En to each pixel circuit through an emission control line EL. The second scan driving circuit SDRV2 may be located opposite to the first scan driving circuit SDRV1 with respect to the main display area MDA and may be substantially parallel to the first scan driving circuit SDRV1. Some of the main, intermediate, and auxiliary pixel circuits PCm, PCt, and PCa respectively driving the main pixels Pm, the intermediate pixels Pt, and the auxiliary pixels Pa may be electrically connected to the first scan driving circuit SDRV1, and the others thereof may be electrically connected to the second scan driving circuit SDRV2.

The terminal portion PAD may be arranged at one side of the substrate 100. The terminal portion PAD is exposed without being covered by an insulating layer and connected to a display circuit board 30. A display driver 32 may be arranged at the display circuit board 30.

The display driver 32 may generate a control signal to be transmitted to the first scan driving circuit SDRV1 and the second scan driving circuit SDRV2. The display driver 32 may generate a data signal Dm, and the generated data signal may be transmitted to the main and auxiliary pixel circuits PCm and PCa through a fan-out line FW and a data line DL connected to the fan-out line FW.

The display driver 32 may supply a driving voltage ELVDD to the driving voltage supply line 11 and may supply a common voltage ELVSS to the common voltage supply line 13. The driving voltage ELVDD may be applied to the pixel circuits of the main and auxiliary pixels Pm and Pa through a driving voltage line PL connected to the driving voltage supply line 11, and the common voltage ELVSS may be applied to an opposite electrode 230 of a display element ED through the common voltage supply line 13.

The driving voltage supply line 11 may be provided to extend in the x-direction under the main display area MDA. The common voltage supply line 13 may have a shape in which one side is open in a loop shape, to partially surround the main display area MDA.

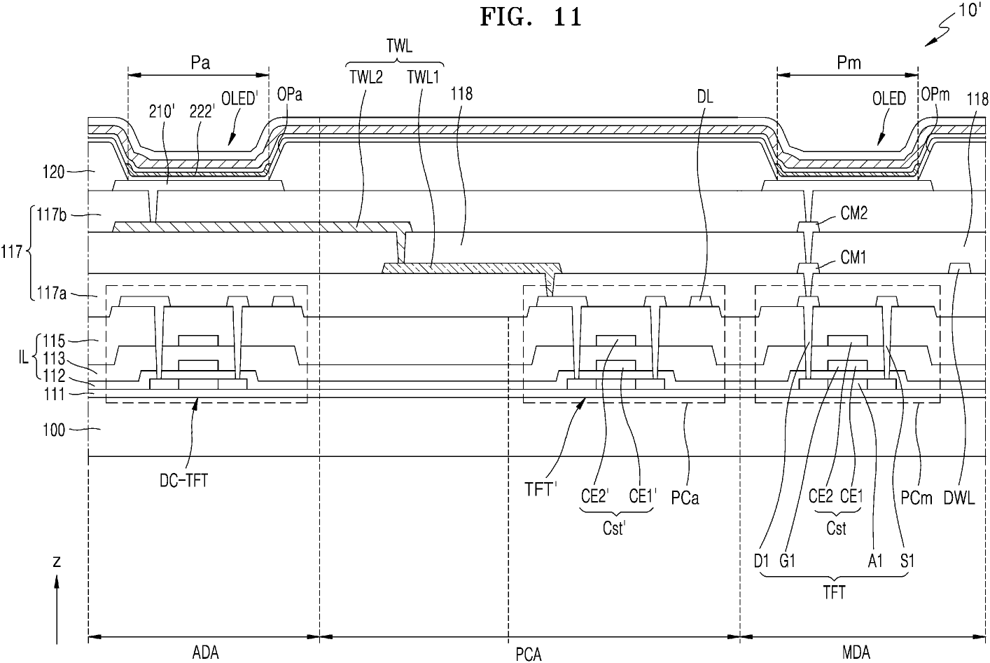

FIG. 11 is a cross-sectional view of an embodiment of a portion of the display panel 10' shown in FIG. 10.

Although FIG. 11 is similar to FIG. 8A, there is a difference in that the driving circuit is arranged in the auxiliary display area ADA, and the auxiliary pixel circuit PCa is arranged in at least a portion of the main display area MDA. Since other configurations are the same as those of the aforementioned embodiment, differences are mainly described below.

Referring to FIG. 11, the main pixel Pm may be arranged in the main display area MDA, and the auxiliary pixel Pa and the driving circuit may be arranged in the auxiliary display area ADA. The auxiliary circuit area PCA may be between the main display area MDA and the auxiliary display area ADA. The main pixel circuit PCm including the main thin-film transistor TFT and the main storage capacitor Cst, the main organic light-emitting diode OLED as a display element ED connected to the main pixel circuit PCm may be arranged in the main display area MDA. Also, the auxiliary pixel circuit PCa including the auxiliary thin-film transistor TFT' and the auxiliary storage capacitor Cst' may be arranged in the auxiliary circuit area PCA. The auxiliary organic light-emitting diode OLED' may be arranged in the auxiliary display area ADA. Moreover, the connection line TWL that extends from the auxiliary circuit area PCA to the auxiliary display area ADA and connects the auxiliary pixel circuit PCa to the auxiliary organic light-emitting diode OLED' may be arranged. Though not illustrated in FIG. 11, a plurality of intermediate pixels Pt (see FIG. 10), a plurality of intermediate pixel circuits PCt (see FIG. 10), and a plurality of auxiliary pixels Pa may be arranged in an area between the auxiliary pixel Pa and the auxiliary pixel circuit PCa which are connected by the connection line TWL. The connection line TWL may be arranged on a different layer from elements of the intermediate pixel Pt, the auxiliary pixel circuit PCa, and the auxiliary organic light-emitting diode OLED', or may be arranged on the same layer as the elements so as not to overlap the elements.

The first sub-line TWL1 may be arranged on the first planarization layer 117a. In an embodiment, the first sub-line TWL1 may be arranged on the same layer as a first connection electrode CM1 and the data connection line DWL.

The second sub-line TWL2 may be arranged on the insulating layer 118. The insulating layer 118 may be a layer added to avoid interference of the second sub-line TWL2 with elements of the main and auxiliary pixel circuits PCm and PCa and the main and auxiliary organic light-emitting diodes OLED and OLED'. In an embodiment, the insulating layer 118 may include an inorganic insulating material. In another embodiment, the insulating layer 118 may include an organic insulating material. In an embodiment, for example, the insulating layer 118 may include the same material as the first planarization layer 117a or the second planarization layer 117b.

The first sub-line TWL1 may be electrically connected to the second sub-line TWL2 through the contact portion CT. In an embodiment, the first sub-line TWL1 and the second sub-line TWL2 may be provided as a plurality of first sub-lines TWL1 and a plurality of second sub-lines TWL2. In an embodiment, for example, the plurality of first sub-lines TWL1 and the plurality of second sub-line TWL2 may be alternately connected to each other so that the connection line TWL is arranged on a different layer from the elements of the intermediate pixel Pt, the auxiliary pixel circuit PCa, and the auxiliary organic light-emitting diode OLED'.

In FIG. 11, the display panel 10' is illustrated, in which one insulating layer 118 is between the first planarization layer 117a and the second planarization layer 117b, and the connection line TWL includes the first sub-line TWL1 and the second sub-line TWL2, but one or more embodiments are not limited thereto. The display panel 10 may not include the insulating layer 118 as described with reference to FIG. 8A. At least a portion of the connection line TWL may be arranged on the same layer as the electrode layers S1 and D1 of the main thin-film transistor TFT constituting main pixel circuit PCm.

Also, the connection line TWL may include three or more sub-lines (e.g., the first sub-line TWL1, the second sub-line TWL2, and the third sub-line TWL3) arranged on different layers, as described above with reference to FIGS. 8C or 8D. At least a portion of the connection line TWL may be arranged on the same layer as the gate electrode G1 of the main thin-film transistor TFT constituting the main pixel circuit PCm or may be arranged on the same layer as the lower electrode CE1 or the upper electrode CE2 of the main storage capacitor Cst. In order to electrically connect the sub-lines (e.g., the first sub-line TWL1 and the third sub-line TWL3) arranged with a plurality of layers therebetween, the connection line TWL may include a bridge metal BM (see FIG. 8C) between insulating layers.

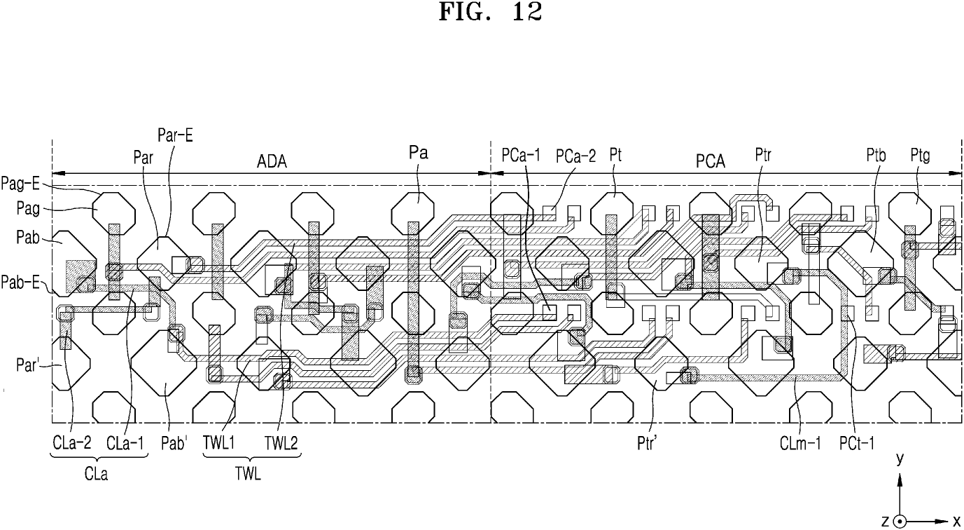

FIG. 12 is a schematic plan view of an embodiment of a portion of a display area of the display panel 10' shown in FIG. 10.

Referring to FIG. 12, the display area DA may include the auxiliary display area ADA and the auxiliary circuit area PCA which is arranged to be in contact with a boundary of the auxiliary display area ADA. That is, the auxiliary display area ADA and the auxiliary circuit area PCA meet each other at the boundary.

An image may be provided in the auxiliary display area ADA and the auxiliary circuit area PCA through an array of a plurality of intermediate and auxiliary pixels Pt and Pa that are arranged two-dimensionally. The auxiliary pixels Pa may be arranged on the auxiliary display area ADA, and the intermediate pixels Pt may be arranged on the auxiliary circuit area PCA.

The auxiliary pixels Pa may include a red auxiliary pixel Par, a green auxiliary pixel Pag, and a blue auxiliary pixel Pab. In an embodiment, as illustrated in FIG. 12, the red auxiliary pixel Par, the green auxiliary pixel Pag, and the blue auxiliary pixel Pab may be arranged in a pentile type. In another embodiment, the red auxiliary pixel Par, the green auxiliary pixel Pag, and the blue auxiliary pixel Pab may also be arranged in a stripe type.

The red auxiliary pixel Par, the green auxiliary pixel Pag, and the blue auxiliary pixel Pab may have different sizes (or widths). In an embodiment, for example, sizes of the red auxiliary pixel Par and the blue auxiliary pixel Pab may each be greater than a size of the green auxiliary pixel Pag. In this case, when sizes of the red auxiliary pixel Par and the blue auxiliary pixel Pab are greater than the size of the green auxiliary pixel Pag, it may indicate that an emission area Par-E of the red auxiliary pixel Par and an emission area Pab-E of the blue auxiliary pixel Pab are greater than an emission area Pag-E of the green auxiliary pixel Pag.

The intermediate pixels Pt may include a red intermediate pixel Ptr, a green intermediate pixel Ptg, and a blue intermediate pixel Ptb. In an embodiment, as illustrated in FIG. 12, the red intermediate pixel Ptr, the green intermediate pixel Ptg, and the blue intermediate pixel Ptb may be arranged in a pentile type. In another embodiment, the red intermediate pixel Ptr, the green intermediate pixel Ptg, and the blue intermediate pixel Ptb may also be arranged in a stripe type.

The red intermediate pixel Ptr, the green intermediate pixel Ptg, and the blue intermediate pixel Ptb may have different sizes (or widths). In an embodiment, for example, sizes of the red intermediate pixel Ptr and the blue intermediate pixel Ptb may be greater than a size of the green intermediate pixel Ptg.

Although FIG. 12 illustrates that the intermediate pixels Pt and the auxiliary pixels Pa have the same size (or width) as each other, the intermediate pixels Pt and the auxiliary pixels Pa may have different sizes (or widths) as each other.

The intermediate pixel circuit PCt and the auxiliary pixel circuit PCa may be arranged in the auxiliary circuit area PCA. The intermediate pixel Pt may be arranged to overlap the intermediate pixel circuit PCt and the auxiliary pixel circuit PCa.

In an embodiment, as illustrated in FIG. 12, the main and auxiliary pixels Pm and Pa emitting the same color may be electrically connected to each other and may be driven in common. In an embodiment, for example, the blue auxiliary pixel Pab may be electrically connected to another blue auxiliary pixel Pab' through a first auxiliary electrode line CLa-1 and may be driven in common by a first auxiliary pixel circuit PCa-1. The red auxiliary pixel Par (e.g., a first auxiliary display element) may be electrically connected to another red auxiliary pixel Par' (e.g., second auxiliary display element) through a second auxiliary electrode line CLa-2 and may be driven in common by a second auxiliary pixel circuit PCa-2. The red intermediate pixel Ptr may be electrically connected to another intermediate pixel Ptr' through a first intermediate electrode line CLm-1 and may be driven in common by a first intermediate pixel circuit PCt-1.

The connection line TWL may extend from the auxiliary circuit area PCA to the auxiliary display area ADA and may electrically connect the auxiliary pixel circuit PCa to the auxiliary pixel Pa. One end of the connection line TWL may be electrically connected to the auxiliary pixel circuit PCa, and the other end thereof may be electrically connected to the display element ED of the auxiliary pixel Pa. In this case, the connection line TWL may be directly connected to a pixel electrode of the display element ED or may be electrically connected to the display element through an auxiliary electrode line CLa. Although FIG. 12 illustrates that the connection line TWL is arranged across emission areas of the auxiliary and intermediate pixels Pa and Pt, one or more embodiments are not limited thereto. As described above, in order to prevent interference with display elements, elements of the auxiliary and intermediate pixel circuits PCa and PCt, and other lines, the connection line TWL may be at least partially curved on a plane.

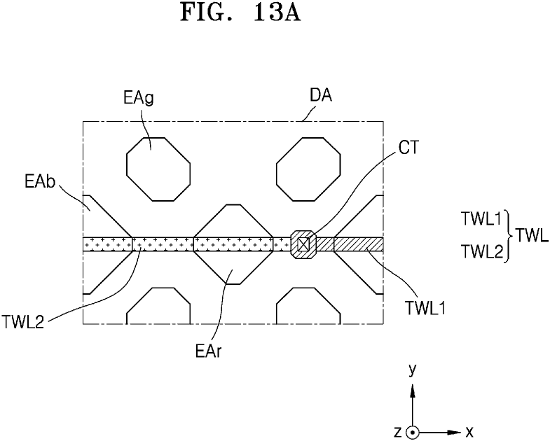

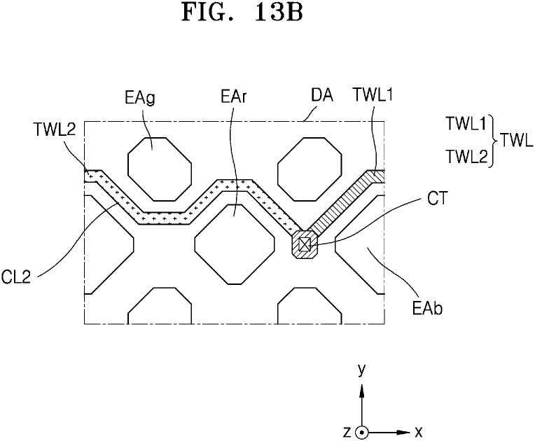

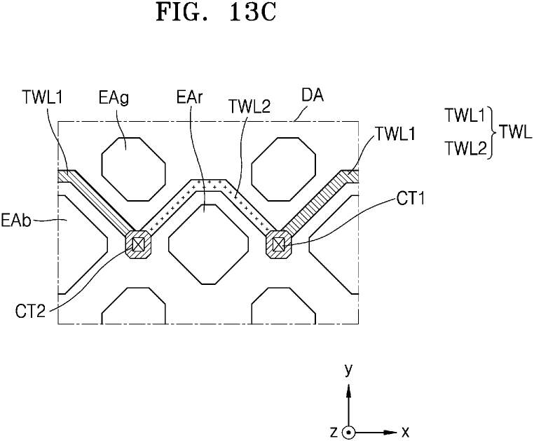

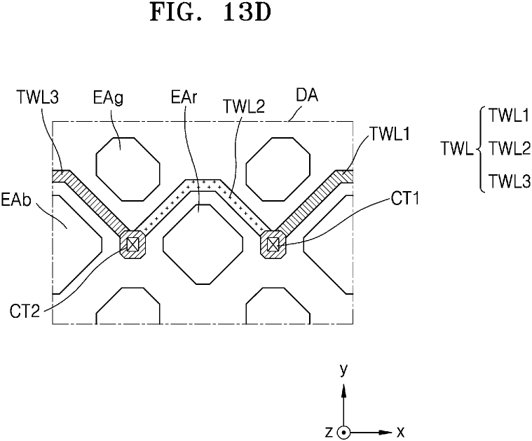

FIGS. 13A to 13Dare schematic plan views of embodiments of a portion of a display area DA.

Referring to FIG. 13A, a connection line TWL may be arranged on the display area DA including a plurality of pixels (e.g., a main pixel Pm, an auxiliary pixel Pa, and/or an intermediate pixel Pt). The display area DA may include red, blue, and green emission areas EAr, EAb, and EAg defined by the pixel-defining layer 120 (see FIG. 8A). As described above, the red emission area EAr, the blue emission area EAb, and the green emission area EAg may have different sizes (or widths). In an embodiment, for example, the blue emission area EAb and the red emission area EAr may be greater than the green emission area EAg.

The connection line TWL may include a first sub-line TWL1 and a second sub-line TWL2 which are arranged on different layers. The first sub-line TWL1 may be electrically connected to the second sub-line TWL2 through a contact portion CT. The contact portion CT may be arranged in an area between the red, blue, and green emission areas EAr, EAb, and EAg. Since the connection line TWL includes the first and second sub-lines TWL1 and TWL2 which are arranged on different layers, when the connection line TWL is provided as a single body, electrical charges introduced into a single metal layer constituting the connection line TWL may be distributed to different metal layers. Accordingly, the introduction of charges through the connection line TWL may be reduced or blocked, thereby reducing a pixel defect due to static electricity.

The connection line TWL may be arranged to overlap the red, blue, and green emission areas EAr, EAb, and EAg. Therefore, the length of the connection line TWL may be shortened to reduce resistance of the connection line TWL, and wiring may be facilitated.

Referring to FIG. 13B, the connection line TWL may include a first sub-line TWL1 and a second sub-line TWL2 which are arranged on different layers. The first sub-line TWL1 may be electrically connected to the second sub-line TWL2 through a contact portion CT. The contact portion CT may be arranged in an area between the red, blue, and green emission areas EAr, EAb, and EAg. The connection line TWL may be arranged in an area between the red, blue, and green emission areas EAr, EAb, and EAg so as not to overlap the red, blue, and green emission areas EAr, EAb, and EAg. In an embodiment, for example, the connection line TWL may be spaced apart from a boundary of the red, blue, and green emission areas EAr, EAb, and EAg on a plane and may be arranged to surround at least a portion of the red, blue, and green emission areas EAr, EAb, and EAg. Therefore, interference due to the connection line TWL applied to elements of the main, auxiliary, and intermediate pixels Pm, Pa, and Pt may be reduced.

Referring to FIG. 13C, the connection line TWL may include a first sub-line TWL1 and a second sub-line TWL2 which are arranged on different layers. The first contact portion CT1 and the second contact portion CT2 may be arranged in an area between the red, blue, and green emission areas EAr, EAb, and EAg. In an embodiment, as illustrated in FIG. 13C, the first contact portion CT1 and the second contact portion CT2 may be arranged relative to a same one red emission area EAr. At the first contact portion CT1, the first sub-line TWL1 may be electrically connected to the second sub-line TWL2, and at the second contact portion CT2, the second sub-line TWL2 may be electrically connected to the first sub-line TWL1, so that the first sub-line TWL1 and the second sub-line TWL2 are alternately arranged. Therefore, interference of the connection line TWL with elements of the main, auxiliary, and intermediate pixels Pm, Pa, and Pt and other lines.

Referring to FIG. 13D, the connection line TWL may include a first sub-line TWL1, a second sub-line TWL2, and a third sub-line TWL3. The first contact portion CT1 and the second contact portion CT2 may be arranged in an area between the red, blue, and green emission areas EAr, EAb, and EAg. At the first contact portion CT1, the first sub-line TWL1 may be electrically connected to the second sub-line TWL2, and at the second contact portion CT2, the second sub-line TWL2 may be electrically connected to the third sub-line TWL3, so that the first sub-line TWL1, the second sub-line TWL2, and the third sub-line TWL3 are alternately arranged. Therefore, interference of the connection line TWL with elements of the main, auxiliary, and intermediate pixels Pm, Pa, and Pt and other lines.

In FIGS. 13B to 13D, the connection line TWL is arranged in an area between the red, blue, and green emission areas EAr, EAb, and EAg so as not to overlap the red, blue, and green emission areas EAr, EAb, and EAg, but depending on a layer in which the first, second, and third sub-lines TWL1, TWL2, and TWL3 are arranged, at least a portion of the first, second, and third sub-lines TWL1, TWL2, and TWL3 may be arranged to overlap the red, blue, and green emission areas EAr, EAb, and EAg, thereby shortening the length of the connection line TWL and facilitating wiring.

According to the one or more embodiments as described above, a display apparatus 1 in which a pixel defect due to static electricity is significantly reduced by blocking introduction of charges through a connection line may be implemented. However, the disclosure is not limited by the effects.

It should be understood that embodiments described herein should be considered in a descriptive sense only and not for purposes of limitation. Descriptions of features within each embodiment should typically be considered as available for other similar features in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate including an auxiliary display area and an auxiliary circuit area outside of the auxiliary circuit area;
a plurality of layers on the substrate including:
an auxiliary display element on the auxiliary display area;
an auxiliary circuit on the auxiliary circuit area and connected to the auxiliary display element; and
a connection line extending from the auxiliary circuit area to the auxiliary display area, the connection line connecting the auxiliary pixel circuit to the auxiliary display element,
wherein the connection line includes a first sub-line and a second sub-line which are on different layers among the plurality of layers on the substrate.

2. The display apparatus of claim 1, wherein
the auxiliary pixel circuit includes a thin-film transistor and a storage capacitor,
the thin-film transistor includes a semiconductor layer, a gate electrode corresponding to the semiconductor layer, and an electrode layer on the gate electrode, and
the first sub-line and the gate electrode are on a same layer.

3. The display apparatus of claim 1, wherein
the auxiliary pixel circuit includes a thin-film transistor and a storage capacitor,
the thin-film transistor includes a semiconductor layer, a gate electrode corresponding to the semiconductor layer, and an electrode layer on the gate electrode, and
the first sub-line and the electrode layer are on a same layer.

4. The display apparatus of claim 3, wherein the first sub-line and the electrode layer which are on a same layer, include different materials.

5. The display apparatus of claim 1, wherein
the auxiliary pixel circuit includes a thin-film transistor and a storage capacitor,
the thin-film transistor includes a semiconductor layer, a gate electrode corresponding to the semiconductor layer, and an electrode layer on the gate electrode,
the plurality of layers on the substrate comprises a conductive layer on the electrode layer, and
the first sub-line and the conductive layer are on a same layer.

6. The display apparatus of claim 1, wherein
the auxiliary pixel circuit includes a thin-film transistor and a storage capacitor,
the storage capacitor includes a lower electrode and an upper electrode, and
the first sub-line is on a same layer as the lower electrode or the upper electrode of the storage capacitor.

7. The display apparatus of claim 1, wherein the plurality of layers including:
a first planarization insulating layer; and
a second planarization insulating layer on the first planarization insulating layer; and
the first sub-line is on the first planarization insulating layer, and the second sub-line is on the second planarization insulating layer.

8. The display apparatus of claim 1, wherein
the connection line further includes a third sub-line on a different layer from the first sub-line and the second sub-line, and
the third sub-line is electrically connected to the first sub-line or the second sub-line.

9. The display apparatus of claim 1, wherein
the plurality of layers further include an insulating layer between the first sub-line and the second sub-line.

10. The display apparatus of claim 9, wherein the insulating layer includes an inorganic material or an organic material.

11. The display apparatus of claim 1, wherein
the auxiliary display element is provided in plural including a plurality of auxiliary display elements, and
the display apparatus further comprises an auxiliary electrode line which electrically connects the plurality of auxiliary display elements to each other.

12. The display apparatus of claim 1, wherein
the plurality of layers further include a pixel-defining layer on the substrate and having an opening in the auxiliary display area, the opening in the pixel-defining layer defining an auxiliary emission area,
and the connection line which connects the auxiliary pixel circuit to the auxiliary display element is spaced apart from the auxiliary emission area.

13. The display apparatus of claim 1, wherein within the connection line which connects the auxiliary pixel circuit to the auxiliary display element:
the first sub-line and the second sub-line are provided in plural including a plurality of first sub-lines and a plurality of second sub-lines, respectively, and
the plurality of first sub-lines and the plurality of second sub-lines are alternated along the connection line and connected to each other.

14. The display apparatus of claim 1, wherein the substrate further includes a main display area and a peripheral area outside the main display area, the main display area and the peripheral area being arranged to surround at least a portion of the auxiliary display area, and
the auxiliary circuit area is spaced apart from the auxiliary display area with the main display area therebetween.

15. The display apparatus of claim 14, wherein the peripheral area includes the auxiliary circuit area.

16. The display apparatus of claim 14, wherein
within the connection line, the first sub-line is electrically connected to the second sub-line at a contact portion, and
the contact portion is in the main display area.

17. The display apparatus of claim 1, wherein
the substrate further includes a main display area and a peripheral area outside the main display area, the main display area and the peripheral area being arranged to surround at least a portion of the auxiliary display area, and
the auxiliary circuit area meets the auxiliary display area at a boundary therebetween.

18. The display apparatus of claim 1, wherein a portion of the connection line is in the auxiliary display area and includes a transparent conductive material.

19. The display apparatus of claim 1, wherein the substrate further includes a main display area in which a main display element and a main pixel circuit are arranged, and
the auxiliary display area is arranged in contact with an outer boundary of the auxiliary circuit area.

20. The display apparatus of claim 19, wherein
the plurality of layers on the substrate further comprises a driving circuit which drives the main pixel circuit of the main display area,
wherein the driving circuit corresponds to the auxiliary display area and overlaps the auxiliary display element.
